(19) United States
(12) Patent Application Publication
(10) Pub. No.: US 2026/0293101 A1
(43) Pub. Date: Sep. 24, 2026

(54) SEMICONDUCTOR DEVICE AND METHOD OF MANUFACTURING THE SAME

(71) Applicant: Kioxia Corporation, Tokyo (JP)

(72) Inventors: Ha HOANG, Yokkaichi Mie (JP); Kazuhiro MATSUO, Kuwana Mie (JP); Masaya TODA, Yokkaichi Mie (JP); Yusuke MUTO, Yokkaichi Mie (JP); Yusuke MIKI, Yokkaichi Mie (JP)

(73) Assignee: Kioxia Corporation, Tokyo (JP)

(21) Appl. No.: 19/312,392

(22) Filed: Aug. 28, 2025

(30) Foreign Application Priority Data
Mar. 24, 2025 (JP) 2025-048010

(51) Int. Cl. H10B 12/00; H10D 62/80; H10D 64/66; H10D 64/68

(52) U.S. Cl. CPC H10B 12/33; H10B 12/05; H10D 62/875; H10D 64/667; H10D 64/685; H10D 64/691

(57) ABSTRACT

A semiconductor device includes an oxide semiconductor layer, a first wiring, a gate insulating layer contains oxygen or nitrogen, and a second element, an insulating layer contains at least one element among oxygen, chlorine, and fluorine, and a third element. An absolute value of a difference between a first electronegativity of one having a higher atomic concentration of oxygen and nitrogen contained in the gate insulating layer and a second electronegativity of the second element is a first value. An absolute value of a difference between a third electronegativity of an element having a highest atomic concentration among oxygen, chlorine, and fluorine contained in the insulating layer and a fourth electronegativity of the third element contained in the insulating layer is a second value. The second value is larger than the first value.

### CROSS-REFERENCE TO RELATED APPLICATIONS

This application is based upon and claims the benefit of Japanese Patent Application No. 2025-048010, filed on Mar. 24, 2025, the entire contents of which are incorporated herein by reference.

### BACKGROUND

### Field

Embodiments described herein relate generally to a semiconductor device and a method of manufacturing the same.

### Description of the Related Art

There has been known a semiconductor device including an oxide semiconductor layer, a first wiring faced to the oxide semiconductor layer, and a gate insulating film disposed between the oxide semiconductor layer and the first wiring.

### BRIEF DESCRIPTION OF THE DRAWINGS

FIG. 1 is a schematic circuit diagram illustrating a configuration of a part of a semiconductor device according to a first embodiment;

FIG. 2 is a schematic cross-sectional view illustrating a configuration of a part of the semiconductor device;

FIG. 3 is a schematic cross-sectional view illustrating a configuration of a part of the semiconductor device;

FIG. 4 is a schematic plan view illustrating a configuration of a part of the semiconductor device;

FIG. 5 is a schematic plan view illustrating a configuration of a part of the semiconductor device;

FIG. 6 is a schematic plan view illustrating a configuration of a part of the semiconductor device;

FIG. 7 is a schematic cross-sectional view illustrating a configuration of a part of the semiconductor device;

FIG. 8 is a schematic cross-sectional view illustrating a configuration of a part of the semiconductor device;

FIG. 9 is a schematic plan view illustrating a configuration of a part of the semiconductor device;

FIG. 10 is a schematic cross-sectional view for describing a manufacturing method of the semiconductor device;

FIG. 11 is a schematic cross-sectional view for describing the manufacturing method;

FIG. 12 is a schematic plan view for describing the manufacturing method;

FIG. 13 is a schematic cross-sectional view for describing the manufacturing method;

FIG. 14 is a schematic cross-sectional view for describing the manufacturing method;

FIG. 15 is a schematic plan view for describing the manufacturing method;

FIG. 16 is a schematic cross-sectional view for describing the manufacturing method;

FIG. 17 is a schematic cross-sectional view for describing the manufacturing method;

FIG. 18 is a schematic plan view for describing the manufacturing method;

FIG. 19 is a schematic cross-sectional view for describing the manufacturing method;

FIG. 20 is a schematic cross-sectional view for describing the manufacturing method;

FIG. 21 is a schematic plan view for describing the manufacturing method;

FIG. 22 is a schematic cross-sectional view for describing the manufacturing method;

FIG. 23 is a schematic cross-sectional view for describing the manufacturing method;

FIG. 24 is a schematic plan view for describing the manufacturing method;

FIG. 25 is a schematic cross-sectional view for describing the manufacturing method;

FIG. 26 is a schematic cross-sectional view for describing the manufacturing method;

FIG. 27 is a schematic plan view for describing the manufacturing method;

FIG. 28 is a schematic cross-sectional view for describing the manufacturing method;

FIG. 29 is a schematic cross-sectional view for describing the manufacturing method;

FIG. 30 is a schematic plan view for describing the manufacturing method;

FIG. 31 is a schematic cross-sectional view for describing the manufacturing method;

FIG. 32 is a schematic cross-sectional view for describing the manufacturing method;

FIG. 33 is a schematic plan view for describing the manufacturing method;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view for describing the manufacturing method;

FIG. 38 is a schematic cross-sectional view for describing the manufacturing method;

FIG. 39 is a schematic cross-sectional view for describing the manufacturing method;

FIG. 40 is a schematic plan view for describing the manufacturing method;

FIG. 41 is a schematic cross-sectional view for describing the manufacturing method;

FIG. 42 is a schematic cross-sectional view for describing the manufacturing method;

FIG. 43 is a schematic plan view for describing the manufacturing method;

FIG. 44 is a schematic cross-sectional view for describing the manufacturing method;

FIG. 45 is a schematic cross-sectional view for describing the manufacturing method;

FIG. 46 is a schematic plan view for describing the manufacturing method;

FIG. 47 is a schematic cross-sectional view for describing the manufacturing method;

FIG. 48 is a schematic cross-sectional view for describing the manufacturing method;

FIG. 49 is a schematic plan view for describing the manufacturing method;

FIG. 50 is a schematic cross-sectional view for describing the manufacturing method;

FIG. 51 is a schematic cross-sectional view for describing the manufacturing method;

FIG. 52 is a schematic cross-sectional view for describing the manufacturing method;

FIG. 53 is a schematic cross-sectional view for describing the manufacturing method;

FIG. 54 is a schematic cross-sectional view for describing the manufacturing method;

FIG. 55 is a schematic cross-sectional view for describing the manufacturing method;

FIG. 56 is a schematic view for describing a part of a process of the manufacturing method;

FIG. 57 is a schematic view for describing a part of the process of the manufacturing method;

FIG. 58 is a schematic view for describing a part of the process of the manufacturing method;

FIG. 59 is a schematic cross-sectional view illustrating a configuration of a part of a semiconductor device according to a second embodiment;

FIG. 60 is a schematic cross-sectional view for describing a manufacturing method of the semiconductor device;

FIG. 61 is a schematic cross-sectional view for describing the manufacturing method; and

FIG. 62 is a schematic plan view for describing the manufacturing method.

### DETAILED DESCRIPTION

A semiconductor device according to one embodiment comprises: a substrate; an oxide semiconductor layer that extends in a first direction intersecting with a surface of the substrate and contains a first element and oxygen (O); a first wiring faced to at least a part of the oxide semiconductor layer; a gate insulating layer that is disposed between the first wiring and the oxide semiconductor layer and at least contains one element of oxygen (O) or nitrogen (N); an insulating layer that includes a first part provided between the first wiring and the gate insulating layer and contains at least one element among oxygen (O), chlorine (Cl), and fluorine (F); and a barrier conductive layer that includes a second part provided between the first wiring and the insulating layer. When an electronegativity of one element having a higher atomic concentration of oxygen (O) and nitrogen (N) contained in the gate insulating layer is a first electronegativity, and when an electronegativity of a second element having a highest atomic concentration among elements contained in the gate insulating layer other than oxygen (O) and nitrogen (N) is a second electronegativity, an absolute value of a difference between the first electronegativity and the second electronegativity is a first value. When an electronegativity of an element having a highest atomic concentration among oxygen (O), chlorine (Cl), and fluorine (F) contained in the insulating layer is a third electronegativity, and when an electronegativity of a third element having a highest atomic concentration among elements contained in the insulating layer other than oxygen (O), chlorine (Cl), and fluorine (F) is a fourth electronegativity, an absolute value of a difference between the third electronegativity and the fourth electronegativity is a second value. The second value is larger than the first value.

Next, the semiconductor devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion on a side opposite to the substrate of this configuration. A surface intersecting with the X-direction or the Y-direction is referred to as a side surface, an outer peripheral surface, and the like.

### First Embodiment

### Circuit Configuration

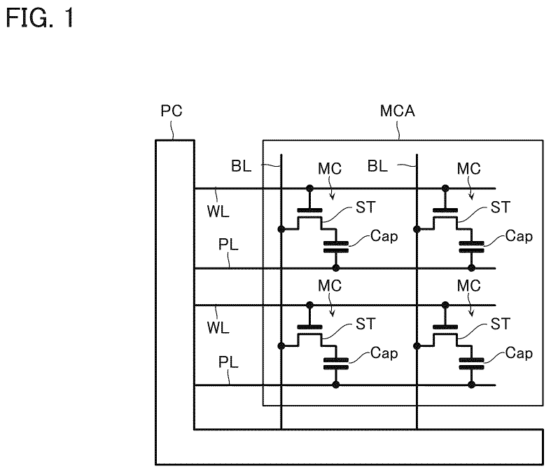

FIG. 1 is a schematic circuit diagram illustrating a configuration of a part of a semiconductor device according to a first embodiment. The semiconductor device according to the first embodiment includes, for example, a memory cell array MCA and a peripheral circuit PC as illustrated in FIG. 1.

The memory cell array MCA includes a plurality of bit lines BL, a plurality of word lines WL, a plurality of plate lines PL, and a plurality of memory cells MC that are connected to these plurality of bit lines BL, plurality of word lines WL, and plurality of plate lines PL. A plurality of memory cells MC connected to one word line WL are connected to the respective mutually different bit lines BL. A plurality of memory cells MC connected to one bit line BL are connected to the respective mutually different word lines WL.

Each of the memory cells MC includes a select transistor ST and a capacitor Cap that are connected in series between the bit line BL and the plate line PL.

The select transistor ST is a field-effect type transistor including a semiconductor layer that functions as a channel region, a gate insulating layer, and a gate electrode. Each gate electrode of the select transistor ST is connected to the word line WL.

The capacitor Cap is a capacitor that includes a pair of electrodes and an insulating film. The capacitor Cap includes a memory portion.

The peripheral circuit PC includes, for example, a voltage generation circuit that generates an operating voltage and outputs the operating voltage to a voltage supply line, a decode circuit that electrically conducts a desired voltage supply line to each of the wirings (the bit lines BL, the word lines WL, and the plate lines PL) in the memory cell array MCA, a sense amplifier circuit that senses a current or a voltage of the bit lines BL, and the like.

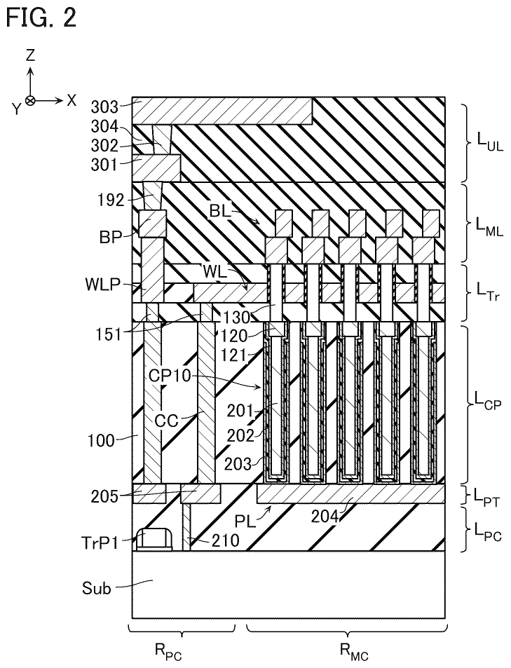

FIG. 2 is a schematic cross-sectional view illustrating a configuration of a part of the semiconductor device. As illustrated in FIG. 2, the semiconductor device according to the first embodiment includes a substrate Sub, a transistor layer L_{Tr} spaced from the substrate Sub in the Z-direction, a wiring layer L_{ML} disposed above the transistor layer L_{Tr}, a wiring layer L_{UL} disposed above the wiring layer L_{ML}, a capacitor layer L_{CP} disposed below the transistor layer L_{Tr}, a plate line layer L_{PT} disposed below the capacitor layer L_{CP}, and a peripheral circuit layer L_{PC} disposed on the substrate Sub below the plate line layer L_{PT}. The substrate Sub contains, for example, P-type silicon (Si) containing P-type impurities, such as boron (B).

As illustrated in FIG. 2, the semiconductor device according to the first embodiment includes a memory region R_{MC} and a peripheral region R_{PC} which are provided on the substrate Sub.

### Structure of Memory Region R_{MC}

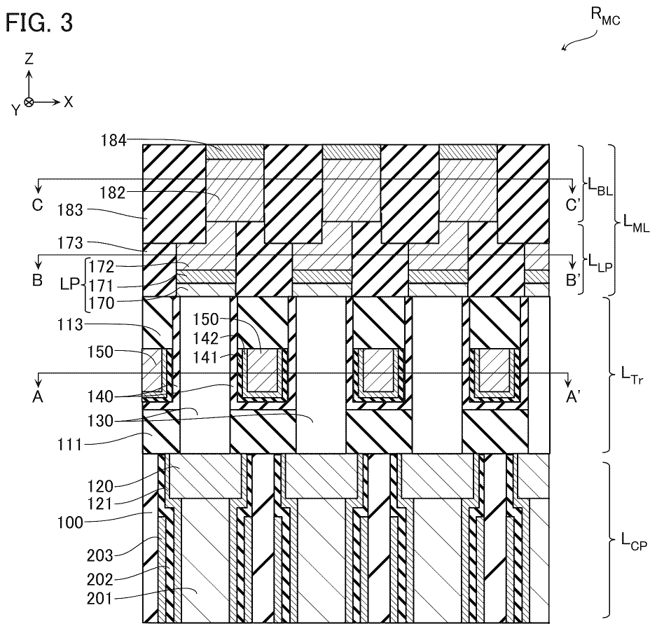

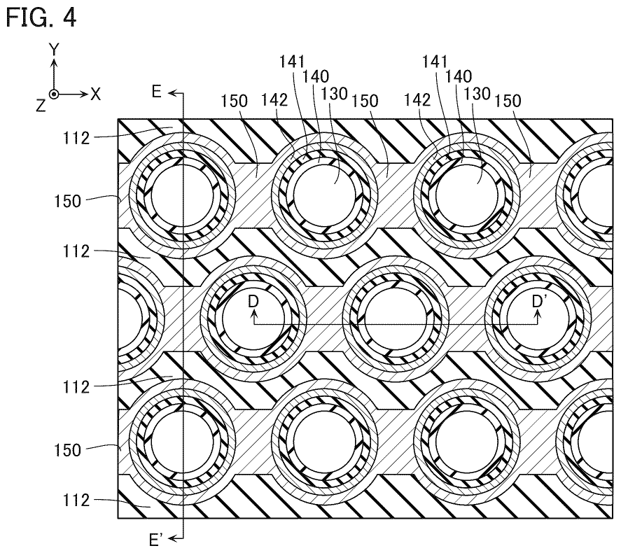

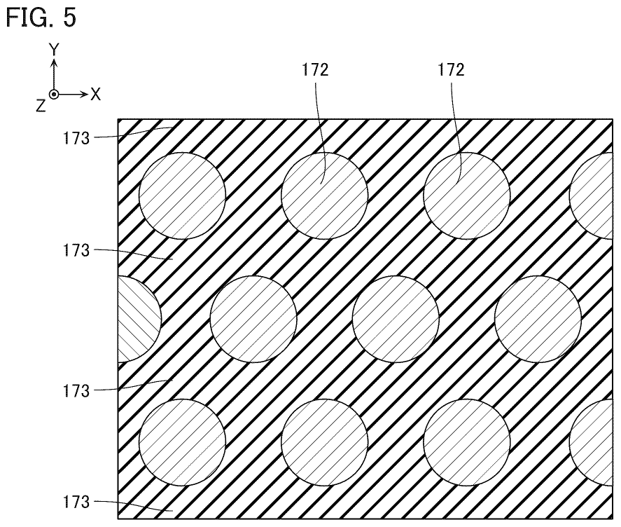

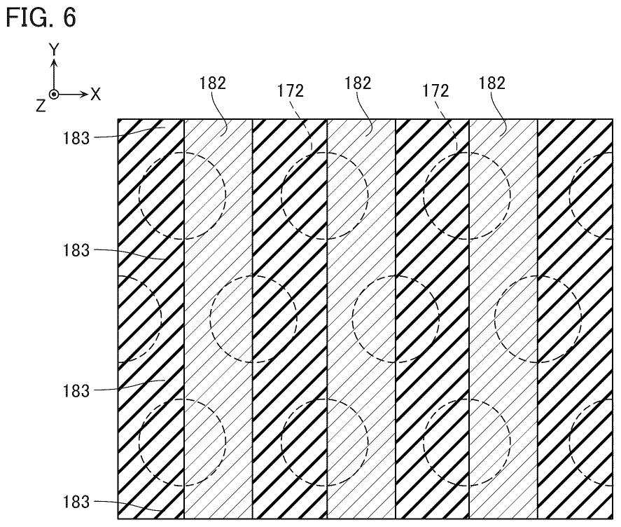

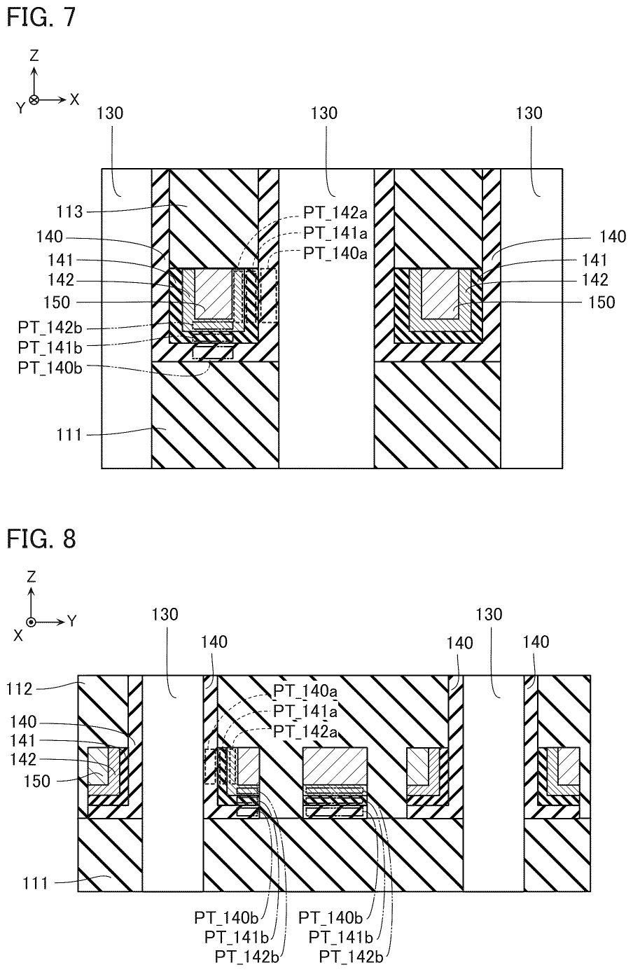

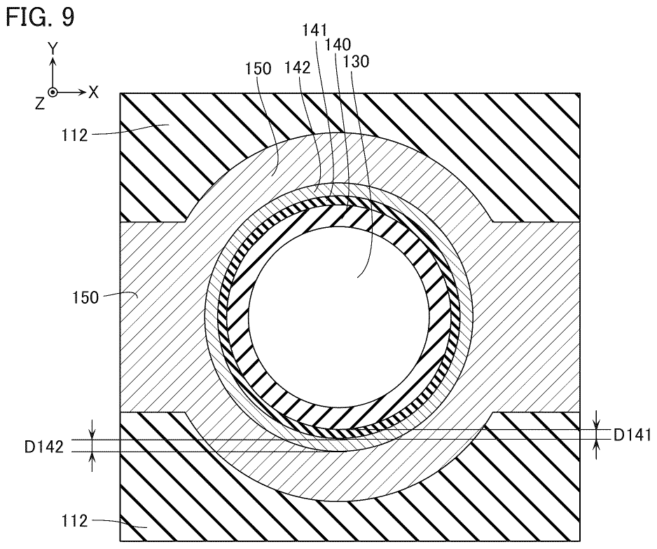

Next, with reference to FIG. 2 to FIG. 9, the structure of the memory region R_{MC} is described. FIG. 3 to FIG. 9 are schematic cross-sectional views and plan views illustrating a configuration of a part of the semiconductor device according to the first embodiment. FIG. 3 illustrates a configuration of a part of the memory region R_{MC}. FIG. 4 is a schematic plan view of the configuration illustrated in FIG. 3 taken along a line A-A′ viewed in an arrow direction. FIG. 5 is a schematic plan view of the configuration illustrated in FIG. 3 taken along a line B-B′ viewed in an arrow direction. FIG. 6 is a schematic plan view of the configuration illustrated in FIG. 3 taken along a line C-C′ viewed in an arrow direction. FIG. 6 illustrates a part of the configuration illustrated in FIG. 5 by dashed lines. FIG. 7 is a schematic cross-sectional view of the configuration illustrated in FIG. 4 taken along a line D-D′ viewed in an arrow direction. FIG. 8 is a schematic cross-sectional view of the configuration illustrated in FIG. 4 taken along a line E-E′ viewed in an arrow direction. FIG. 9 is an enlarged schematic plan view of a part of the configuration illustrated in FIG. 4.

The transistor layer L_{Tr} in the memory region R_{MC} includes, for example, as illustrated in FIG. 3, an insulating layer 111 disposed on an upper surface of the capacitor layer L_{CP} and an insulating layer 113 disposed above the insulating layer 111. The transistor layer L_{Tr} in the memory region R_{MC} includes, for example, as illustrated in FIG. 4, a plurality of insulating layers 112 and a plurality of conductive layers 150 which are disposed between the insulating layer 111 and the insulating layer 113 and alternately arranged in the Y-direction. The transistor layer L_{Tr} in the memory region R_{MC} includes, for example, as illustrated in FIG. 4, a plurality of semiconductor layers 130 arranged in the X-direction corresponding to the conductive layer 150 extending in the X-direction, and insulating layers 140, insulating layers 141, and barrier conductive layers 142 each disposed between the semiconductor layer 130 and conductive layer 150.

For example, as illustrated in FIG. 4, in the two conductive layers 150 adjacent in the Y-direction, a plurality of the semiconductor layers 130 arranged corresponding to one conductive layer 150 and a plurality of the semiconductor layers 130 arranged corresponding to the other conductive layer 150 may be mutually different in position in the X-direction.

The insulating layer 111, the insulating layer 112, and the insulating layer 113 contain, for example, silicon oxide (SiO₂).

The semiconductor layer 130 extends, for example, in the Z-direction, and has an approximately columnar shape. The semiconductor layer 130 is an oxide semiconductor, and functions as, for example, a channel region of the select transistor ST (FIG. 1). For example, the semiconductor layer 130 contains at least one element selected from an element group GP1, and oxygen (O).

The element group GP1 includes indium (In), gallium (Ga), zinc (Zn), magnesium (Mg), aluminum (Al), manganese (Mn), tin (Sn), titanium (Ti), calcium (Ca), and cadmium (Cd).

The semiconductor layer 130 may contain, for example, indium (In), zinc (Zn), and oxygen (O), may contain indium (In), gallium (Ga), and oxygen (O), may contain gallium (Ga), zinc (Zn), and oxygen (O), may contain indium (In), gallium (Ga), zinc (Zn), and oxygen (O), may contain indium (In), gallium (Ga), tin (Sn), and oxygen (O), and may contain indium (In), tungsten (W), and oxygen (O).

The insulating layer 140 is disposed, for example, on at least a part of an outer peripheral surface of the semiconductor layer 130. The insulating layer 140 functions as, for example, a gate insulating layer of the select transistor ST (FIG. 1). The insulating layer 140 at least contains one element of oxygen (O) or nitrogen (N). The insulating layer 140 contains at least one element having the highest atomic concentration among the elements contained in the insulating layer 140 other than oxygen (O) and nitrogen (N).

The insulating layer 140 may be, for example, silicon oxide (SiO₂) containing oxygen (O) and silicon (Si) as an element having the highest atomic concentration among the elements contained in the insulating layer 140 other than oxygen (O). The insulating layer 140 may be, for example, silicon nitride (SiN) containing nitrogen (N) and silicon (Si) as an element having the highest atomic concentration among the elements contained in the insulating layer 140 other than nitrogen (N). The insulating layer 140 may be, for example, a stacked film of silicon oxide (SiO₂) and silicon nitride (SiN) containing oxygen (O), nitrogen (N), and silicon (Si) as an element having the highest atomic concentration among the elements contained in the insulating layer 140 other than oxygen (O) and nitrogen (N).

For example, as illustrated in FIG. 7 and FIG. 8, the insulating layer 140 includes a part PT_140a provided between the conductive layer 150 and the semiconductor layer 130 in the X-direction and the Y-direction, and a part PT_140b provided on one side (lower side) of the conductive layer 150 in the Z-direction. The part PT_140a and the part PT_140b may be continuously provided via a part containing the same material.

For example, as illustrated in FIG. 3 and FIG. 7, the insulating layer 141 is disposed between the conductive layer 150 and the insulating layer 140. For example, as described later, the insulating layer 141 functions as a base layer for properly forming the barrier conductive layer 142. For example, the insulating layer 141 contains at least one element among oxygen (O), chlorine (Cl), and fluorine (F), and at least one element that has the highest atomic concentration among the elements contained in the insulating layer 141 other than oxygen (O), chlorine (Cl), and fluorine (F) and is selected from an element group GP2.

The element group GP2 includes aluminum (Al), titanium (Ti), zinc (Zn), hafnium (Hf), yttrium (Y), scandium (Sc), tantalum (Ta), lanthanum (La), and vanadium (V).

The insulating layer 141 may be, for example, an oxide containing oxygen (O) and at least one element that has the highest atomic concentration among the elements contained in the insulating layer 141 other than oxygen (O) and is selected from the element group GP2. The insulating layer 141 may be, for example, aluminum oxide (AlO), titanium oxide (TiO), zinc oxide (ZnO), hafnium oxide (HfO), yttrium oxide (YO), scandium oxide (ScO), tantalum oxide (TaO), lanthanum oxide (LaO), and vanadium oxide (VO).

The insulating layer 141 may be, for example, a chloride containing chlorine (Cl) and at least one element that has the highest atomic concentration among the elements contained in the insulating layer 141 other than chlorine (Cl) and is selected from the element group GP2. The insulating layer 141 may be, for example, aluminum chloride (AlCl), titanium chloride (TiCl), zinc chloride (ZnCl), hafnium chloride (HfCl), yttrium chloride (YCl), scandium chloride (ScCl), tantalum chloride (TaCl), lanthanum chloride (LaCl), and vanadium chloride (VCl).

The insulating layer 141 may be, for example, a fluoride containing fluorine (F) and at least one element that has the highest atomic concentration among the elements contained in the insulating layer 141 other than fluorine (F) and is selected from the element group GP2. The insulating layer 141 may be, for example, aluminum fluoride (AlF), titanium fluoride (TiF), zinc fluoride (ZnF), hafnium fluoride (HfF), yttrium fluoride (YF), scandium fluoride (ScF), tantalum fluoride (TaF), lanthanum fluoride (LaF), and vanadium fluoride (VF).

The insulating layer 141 may be, for example, a stacked film of the oxides, the chlorides, and the fluorides listed above. The insulating layer 141 may be, for example, a material in which at least any one of nitrogen (N), carbon (C), fluorine (F), and chlorine (Cl) is added to the oxides, the chlorides, and the fluorides listed above.

For example, as illustrated in FIG. 3, FIG. 7, and FIG. 8, the insulating layer 141 may have a surface on one side in contact with the insulating layer 140 and a surface on the other side in contact with the barrier conductive layer 142. The insulating layer 141 may have a width D141 (FIG. 9) of 1 nm or less between the insulating layer 140 and the barrier conductive layer 142. The insulating layer 141 may have a dielectric constant higher than a dielectric constant of the insulating layer 140.

For example, as illustrated in FIG. 7 and FIG. 8, the insulating layer 141 includes a part PT_141a provided between the conductive layer 150 and the insulating layer 140 in the X-direction and the Y-direction, and a part PT_141b provided on one side (lower side) in the Z-direction of the conductive layer 150. The part PT_141a and the part PT_141b may be continuously provided via a part containing the same material.

For example, as illustrated in FIG. 3 and FIG. 7, the barrier conductive layer 142 is disposed between the conductive layer 150 and the insulating layer 141. For example, as described later, the barrier conductive layer 142 functions as a base layer for properly forming the conductive layer 150. The barrier conductive layer 142 contains, for example, nitrogen (N) and at least one element selected from a metal element group MG1.

The metal element group MG1 includes titanium (Ti), niobium (Nb), tungsten (W), and molybdenum (Mo).

The barrier conductive layer 142 may be, for example, titanium nitride (TiN), niobium nitride (NbN), tungsten nitride (WN), and molybdenum nitride (MoN).

For example, as illustrated in FIG. 3, FIG. 7, and FIG. 8, the barrier conductive layer 142 may have a surface on one side in contact with the conductive layer 150 and a surface on the other side in contact with the insulating layer 141. The barrier conductive layer 142 may have a width D142 (FIG. 9) of 3 nm or less between the conductive layer 150 and the insulating layer 141.

For example, as illustrated in FIG. 7 and FIG. 8, the barrier conductive layer 142 includes a part PT_142a provided between the conductive layer 150 and the insulating layer 141 in the X-direction and the Y-direction, and a part PT_142b provided between the conductive layer 150 and the part PT_141b of the insulating layer 141 in the Z-direction. The part PT_142a and the part PT_142b may be continuously provided via a part containing the same material.

For example, as illustrated in FIG. 3 and FIG. 4, the conductive layer 150 is faced to a part of the outer peripheral surface of the semiconductor layer 130. For example, in the XY cross-sectional surface illustrated in FIG. 4, the conductive layer 150 has an annular portion surrounding a part of the semiconductor layer 130 and a rectangular portion, and the annular portions and the rectangular portions are continuously provided in the X-direction. The conductive layer 150 functions as, for example, the gate electrodes of the plurality of select transistors ST arranged in the X-direction and the word line WL (FIG. 1) of the memory cell array MCA. The conductive layer 150 may contain, for example, tungsten (W), molybdenum (Mo), ruthenium (Ru), and cobalt (Co).

The wiring layer L_{ML} of the memory region R_{MC} includes, for example, as illustrated in FIG. 3, a plug layer L_{LP} disposed on an upper surface of the transistor layer L_{Tr}, and a bit line layer L_{BL} disposed on an upper surface of the plug layer L_{LP}.

For example, as illustrated in FIG. 3 and FIG. 5, the plug layer L_{LP} includes a conductive layer 170, a conductive layer 171, and a conductive layer 172, which are disposed on the upper surface of the transistor layer L_{Tr} in the order at the position corresponding to the semiconductor layer 130. Each of the conductive layer 170, the conductive layer 171, and the conductive layer 172 is electrically connected to the semiconductor layer 130. Hereinafter, a structure including the conductive layer 170, the conductive layer 171, and the conductive layer 172 is referred to as a plug LP in some cases.

For example, as illustrated in FIG. 3 and FIG. 5, a plurality of the plugs LP extend in the Z-direction, and are arranged in the X-direction and the Y-direction. For example, the plug LP functions as a source electrode of the select transistor ST. Insulating layers 173 of silicon oxide (SiO₂) or the like are disposed between the plurality of plugs LP.

The conductive layer 170 contains, for example, at least one element selected from a metal element group MG2, and oxygen (O). The metal element group MG2 includes indium (In), gallium (Ga), zinc (Zn), magnesium (Mg), aluminum (Al), manganese (Mn), tin (Sn), niobium (Nb), titanium (Ti), tantalum (Ta), calcium (Ca), tungsten (W), and molybdenum (Mo). The conductive layer 170 may be, for example, indium tin oxide (InSnO).

The conductive layer 171 contains, for example, titanium nitride (TiN), titanium oxide (TiO), and the like.

The conductive layer 172 contains, for example, tungsten (W), aluminum (Al), molybdenum (Mo), and the like.

For example, as illustrated in FIG. 3 and FIG. 6, the bit line layer L_{BL} includes a conductive layer 182 and a conductive layer 184 disposed on a part of an upper surface of the plug layer L_{LP} in this order at the position corresponding to the conductive layer 172. The conductive layer 182 and the conductive layer 184 are electrically connected to a plurality of conductive layers 172 arranged in the Y-direction corresponding to the conductive layer 182 and the conductive layer 184 (FIG. 6).

For example, as illustrated in FIG. 3 and FIG. 6, a structure including the conductive layer 182 and the conductive layer 184 extends in the Y-direction, and a plurality of the structures are arranged in the X-direction. The conductive layer 182 and the conductive layer 184 function as, for example, the bit lines BL (FIG. 1) of the memory cell array MCA. An insulating layer 183 of silicon oxide (SiO₂) or the like is disposed between these structures arranged in the X-direction.

The conductive layer 182 contains, for example, a metal element, such as tungsten (W), aluminum (Al), and molybdenum (Mo).

The conductive layer 184 contains, for example, titanium nitride (TiN).

For example, as illustrated in FIG. 2 and FIG. 3, the capacitor layer L_{CP} in the memory region R_{MC} includes a plurality of conductive layers 120 disposed corresponding to the plurality of semiconductor layers 130 and connected to respective lower ends of the plurality of semiconductor layers 130, a plurality of conductive layers 201 disposed corresponding to these plurality of conductive layers 120 and connected to respective lower ends of the plurality of conductive layers 120, and a plurality of conductive layers 121 disposed on outer peripheral surfaces of these plurality of conductive layers 120 and outer peripheral surfaces and lower surfaces of the plurality of conductive layers 201. The capacitor layer L_{CP} includes insulating layers 202 disposed on outer peripheral surfaces and lower surfaces of the conductive layers 121 and conductive layers 203 disposed on outer peripheral surfaces and lower surfaces of the insulating layers 202 (FIG. 3). In the following description, these configurations that achieve the capacitor Cap (FIG. 1) disposed in the capacitor layer L_{CP} of the memory region R_{MC} are referred to as a “capacitor structure CP10” in some cases. The capacitor structure CP10 includes, for example the conductive layer 120, the conductive layer 121, the conductive layer 201, the insulating layer 202, and the conductive layer 203. Between a plurality of the capacitor structures CP10, for example, an insulating layer 100 of silicon oxide (SiO₂) or the like is disposed.

The conductive layer 120 functions as, for example, a drain electrode of the select transistor ST (FIG. 1) and a part of one electrode of the capacitor Cap (FIG. 1). The conductive layer 120 may has an approximately circular shape in the XY cross-sectional surface, and may have a plug shape. The conductive layer 120 contains, for example, a material similar to that of the conductive layer 170. The conductive layer 120 may be, for example, indium tin oxide (InSnO).

The conductive layer 121 functions as, for example, a part of the one electrode of the capacitor Cap (FIG. 1). The conductive layer 121 may be, for example, titanium nitride (TiN).

The conductive layer 201 functions as a part of the one electrode of the capacitor Cap (FIG. 1). The conductive layer 201 includes, for example, a stacked structure of titanium nitride (TiN) and tungsten (W). The conductive layer 201 may contain, for example, silicon germanium (SiGe), germanium (Ge), and the like, and may contain a material in which boron (B) is added to these materials.

The insulating layer 202 functions as an insulating layer between the electrodes of the capacitor Cap (FIG. 1). The insulating layer 202 contains, for example, aluminum oxide (AlO). The insulating layer 202 may be, for example, silicon oxide (SiO₂) or another insulating metal oxide.

The conductive layer 203 functions as, for example, the other electrode of the capacitor Cap (FIG. 1). The conductive layer 203 includes, for example, a stacked structure of titanium nitride (TiN) and tungsten (W).

For example, as illustrated in FIG. 2, the plate line layer L_{PT} in the memory region R_{MC} includes a conductive layer 204 disposed at a lower surface of the capacitor layer L_{CP}. The conductive layer 204 is electrically connected to a plurality of the conductive layers 203. The conductive layer 204 functions as, for example, a plate line PL (FIG. 1). The conductive layer 204 may contain, for example, tungsten (W) or a stacked structure of titanium nitride (TiN) and tungsten (W).

### Structure of Peripheral Region R_{PC}

Next, the structure of the peripheral region R_{PC} is described with reference to FIG. 2.

The transistor layer L_{Tr} in the peripheral region R_{PC} includes, for example, as illustrated in FIG. 2, an electrode WLP and an electrode 151. The electrode WLP has, for example, an upper end connected to a conductive layer BP, and a lower end connected to the electrode 151. The electrode WLP and the electrode 151 include a stacked structure of titanium nitride (TiN) and tungsten (W), and the like.

The wiring layer L_{ML} in the peripheral region R_{PC} includes the conductive layer BP disposed at the same layer as the bit line BL, and an electrode 192 connected to an upper surface of the conductive layer BP.

For example, as illustrated in FIG. 2, the electrode 192 extends in the Z-direction and has an approximately columnar shape. The electrode 192 may include, for example, tungsten (W), or a stacked structure of titanium nitride (TiN) and tungsten (W).

The conductive layer BP (FIG. 2) contains, for example, a material similar to that of the conductive layers 182, 184.

For example, as illustrated in FIG. 2, the capacitor layer L_{CP} in the peripheral region R_{PC} includes a plurality of through electrodes CC extending in the Z-direction.

For example, as illustrated in FIG. 2, the through electrode CC has an upper end connected to the electrode 151 of the transistor layer L_{Tr}, and a lower end electrically connected to parts of a plurality of conductive layers 205 in the plate line layer L_{PT} (FIG. 2). The through electrode CC includes, for example, a stacked structure of tungsten (W) and titanium nitride (TiN).

For example, as illustrated in FIG. 2, the plate line layer L_{PT} in the peripheral region R_{PC} includes the plurality of conductive layers 205. The conductive layer 205 may contain, for example, a material similar to that of the conductive layer 204.

For example, as illustrated in FIG. 2, the peripheral circuit layer L_{PC} in the peripheral region R_{PC} includes a plurality of transistors TrP1 disposed on the substrate Sub and a plurality of electrodes 210 connected to the plurality of transistors TrP1. The plurality of electrodes 210 have for example, upper ends connected to the conductive layers 205. The plurality of electrodes 210 have, for example, lower ends connected to source regions, drain regions, gate electrodes, and the like of the plurality of transistors TrP1. The plurality of transistors TrP1 constitute, for example, the peripheral circuit PC (FIG. 1).

For example, as illustrated in FIG. 2, the wiring layer L_{UL} includes a wiring 301 disposed on an upper surface of the wiring layer L_{ML}, a wiring 302 disposed to be connected to the wiring 301 on an upper surface of the wiring 301, and a wiring 303 disposed to be connected to the wiring 302 on an upper surface of the wiring 302. An insulating layer 304 of, for example, silicon oxide (SiO₂) is disposed between the wiring 301, the wiring 302, and the wiring 303.

The wiring 301, the wiring 302, and the wiring 303 function as, for example, wirings that apply voltage and current to the peripheral circuit PC and the bit line BL. The wiring 301, the wiring 302, and the wiring 303 contain, for example, copper (Cu), tungsten (W), and aluminum (Al).

### Manufacturing Method of First Embodiment

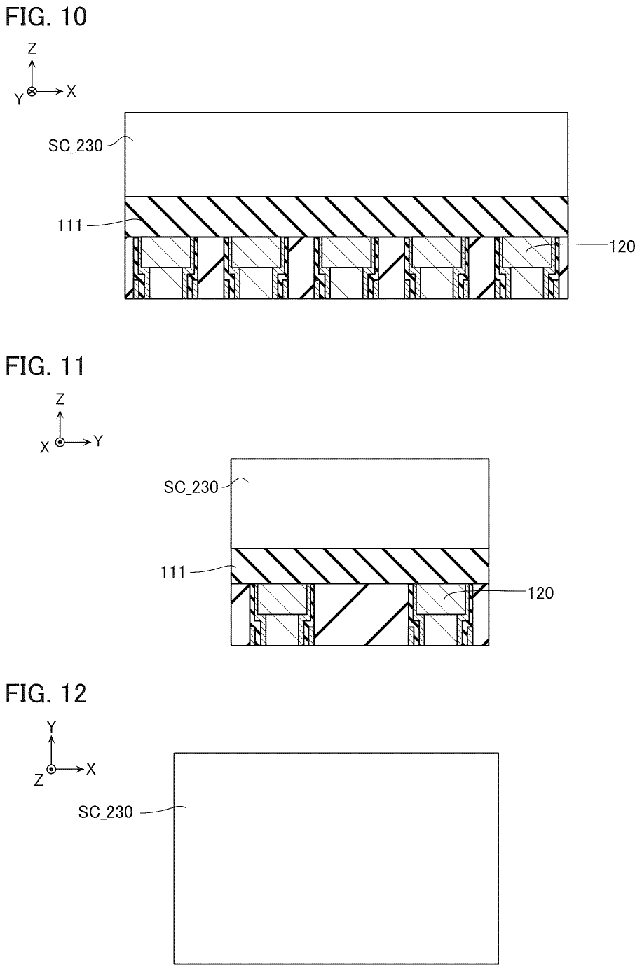

Next, with reference to FIG. 10 to FIG. 55, a manufacturing method of the semiconductor device according to the embodiment is described. FIG. 10 to FIG. 55 are schematic cross-sectional views and plan views for describing a manufacturing method of the semiconductor device according to the first embodiment.

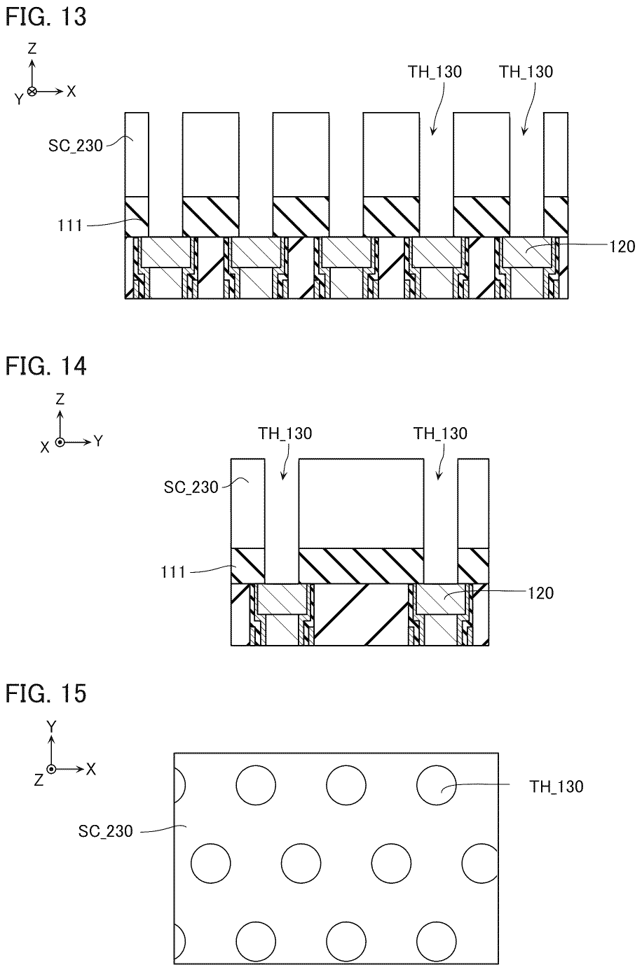

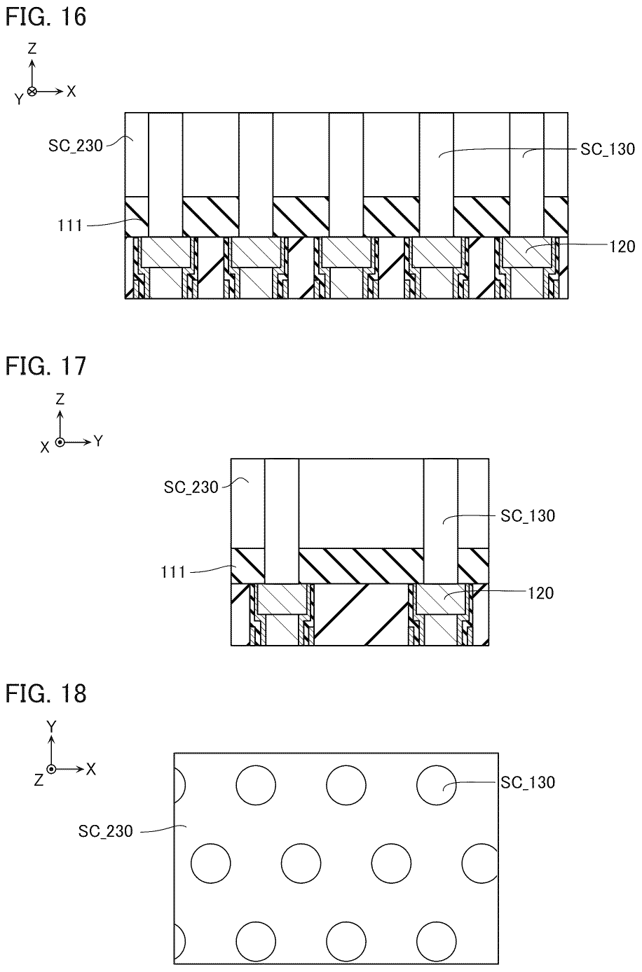

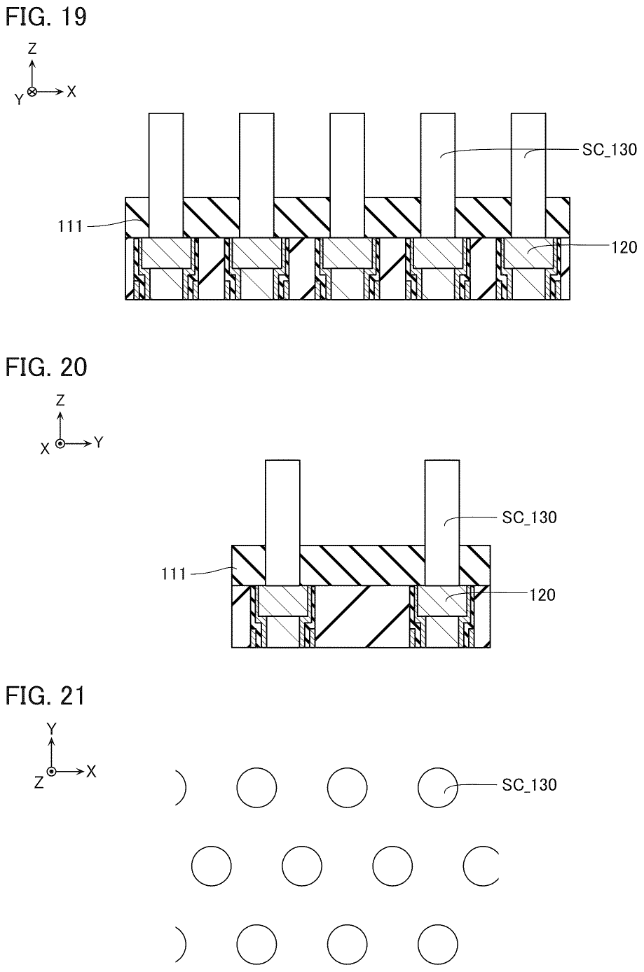

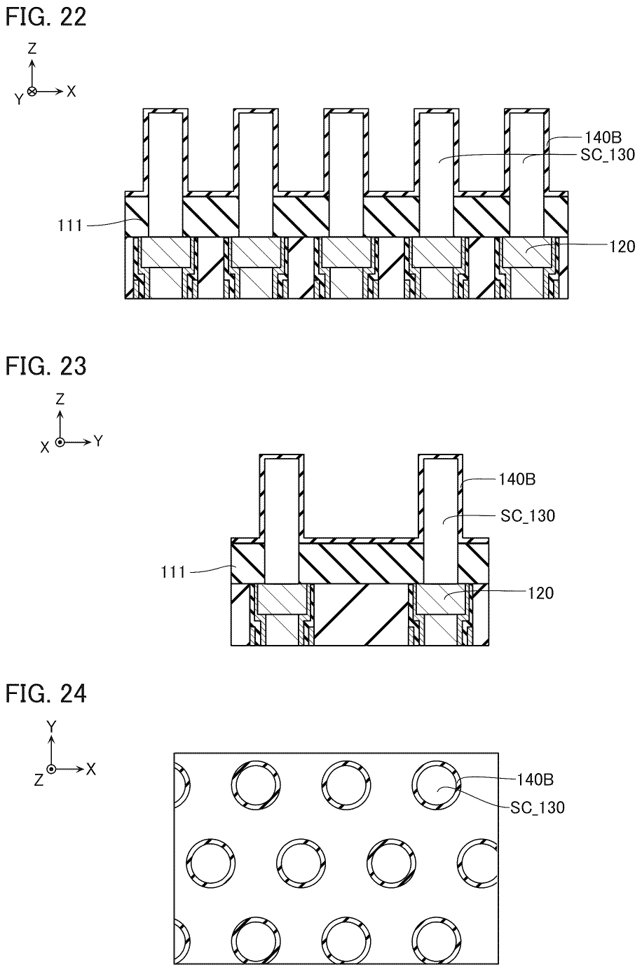

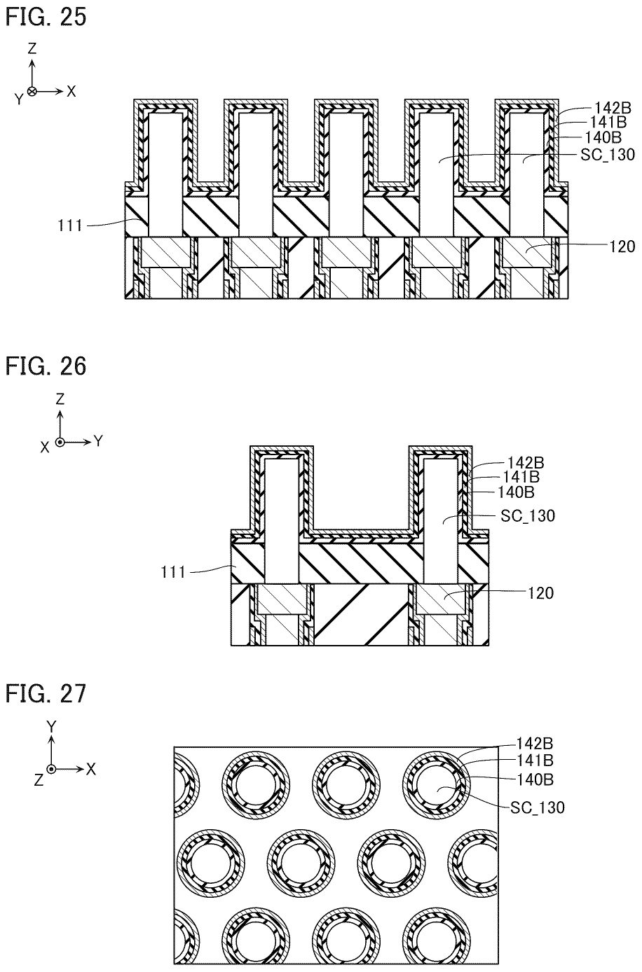

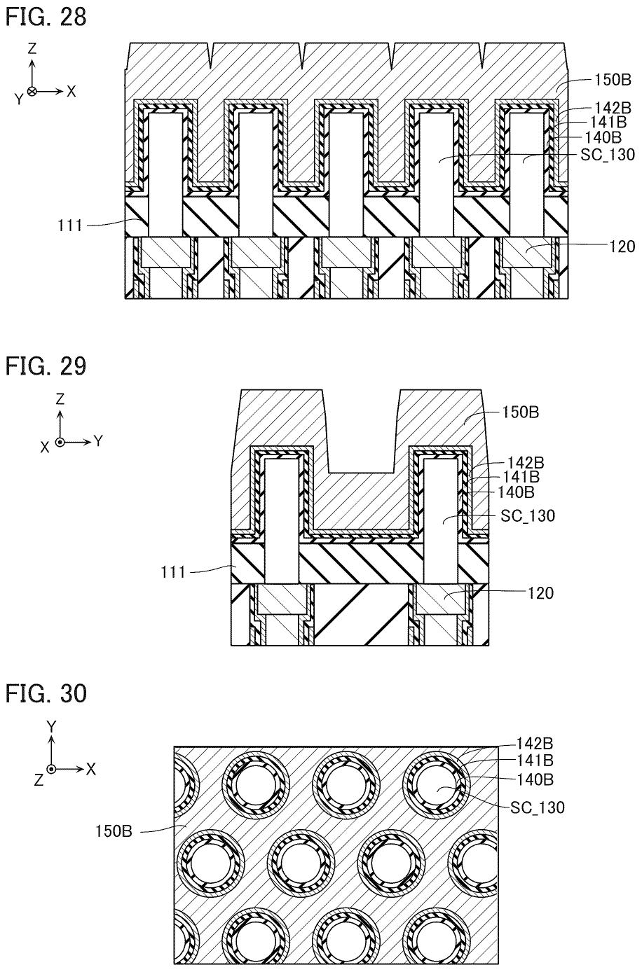

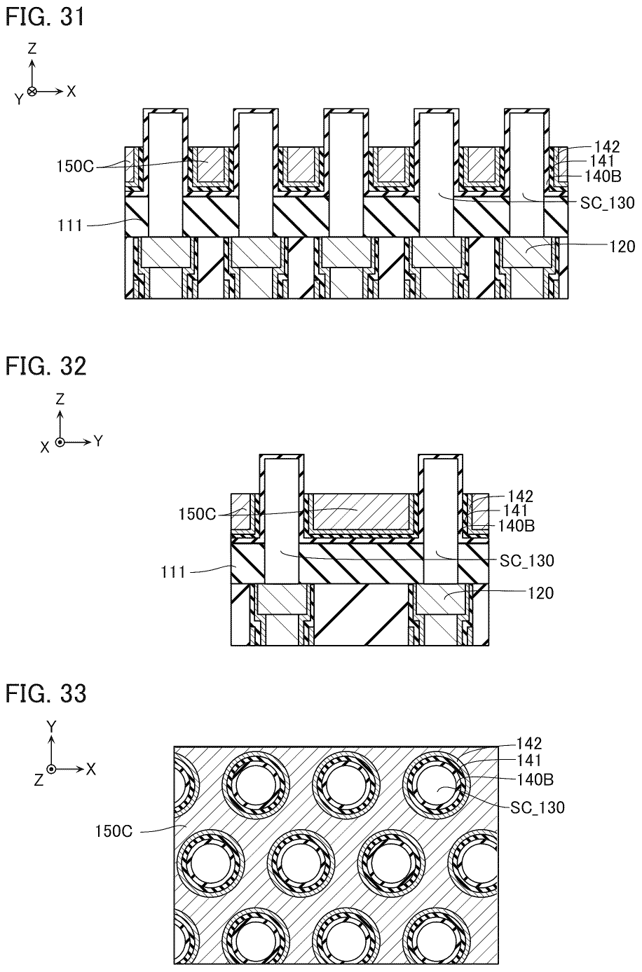

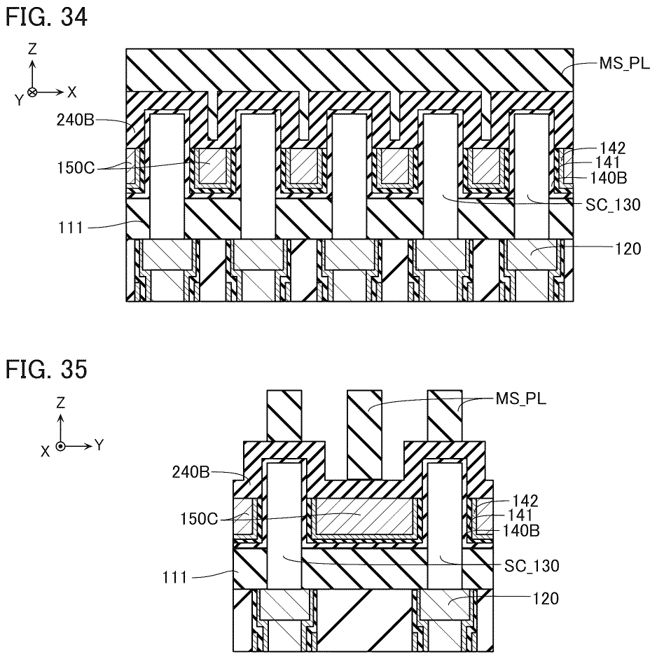

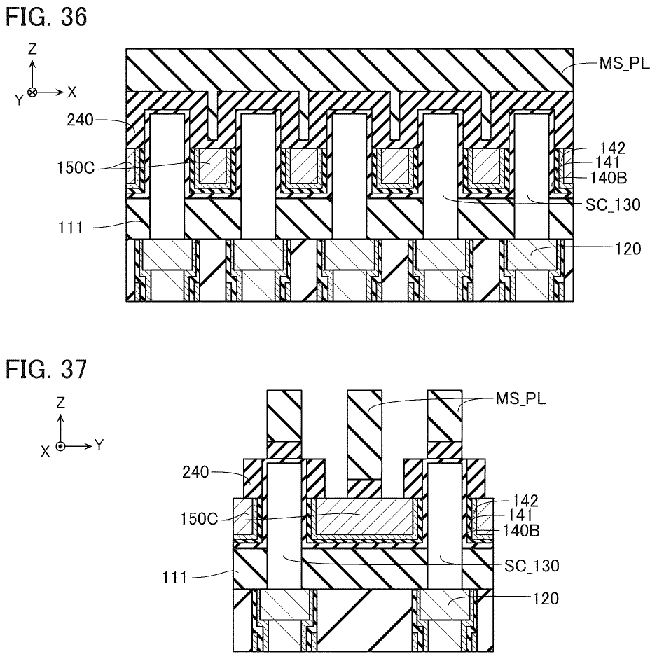

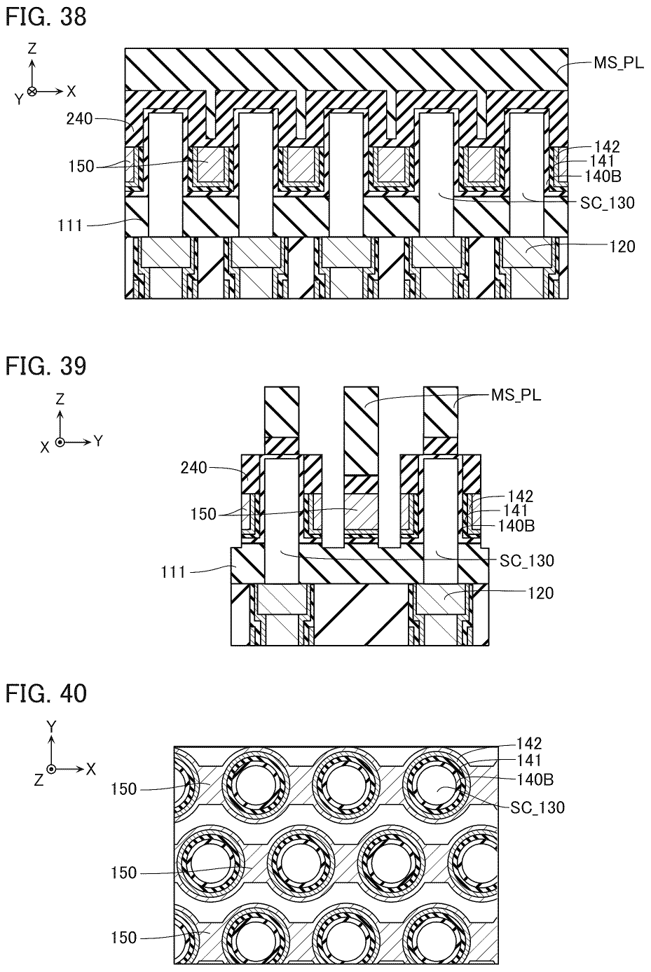

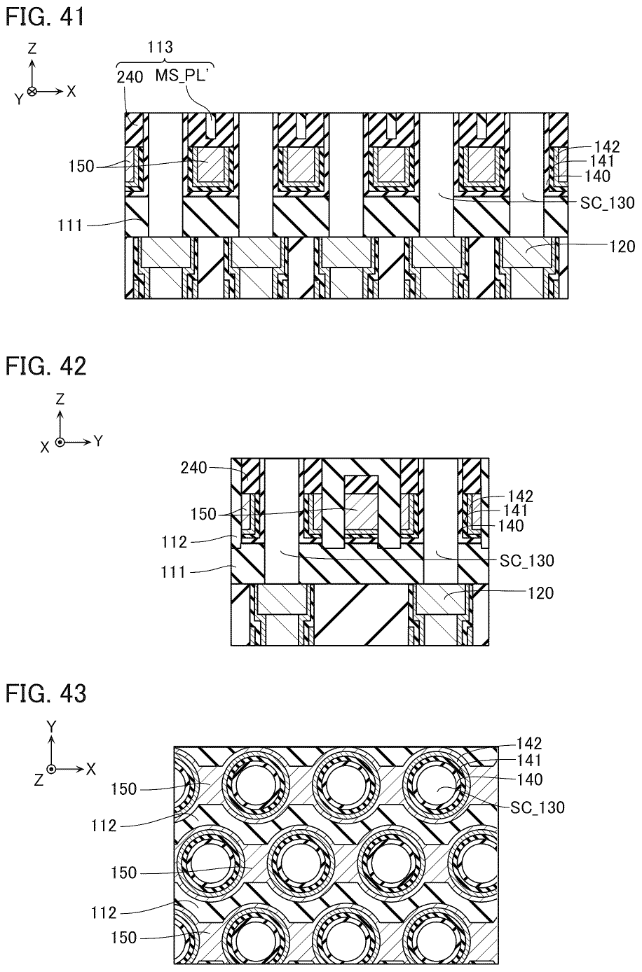

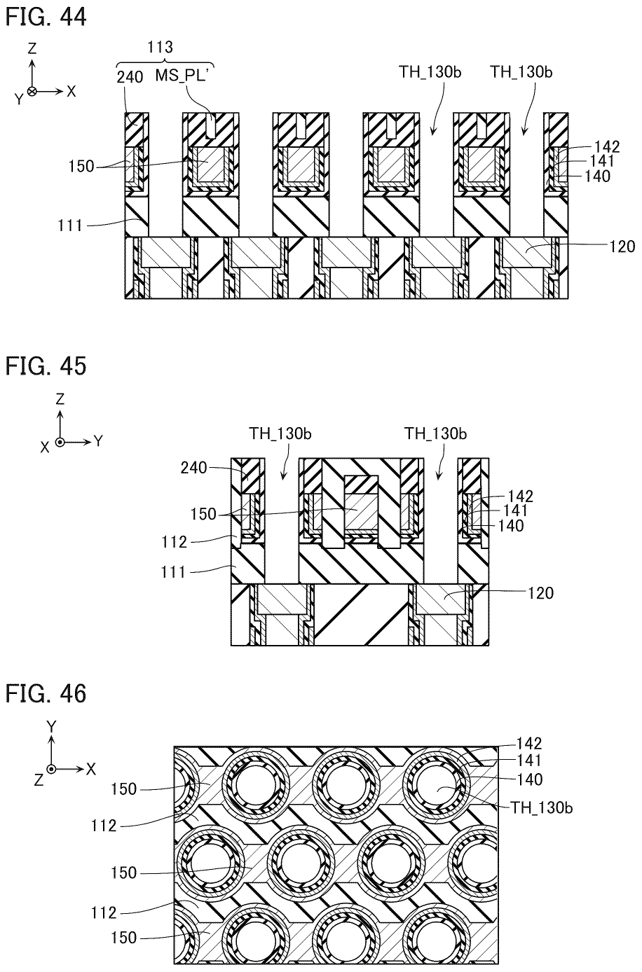

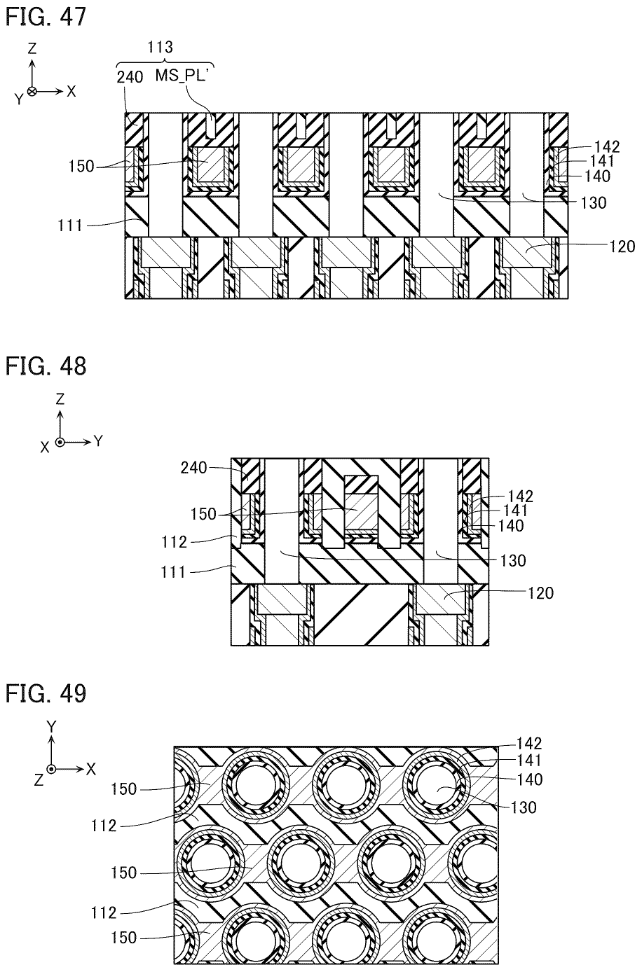

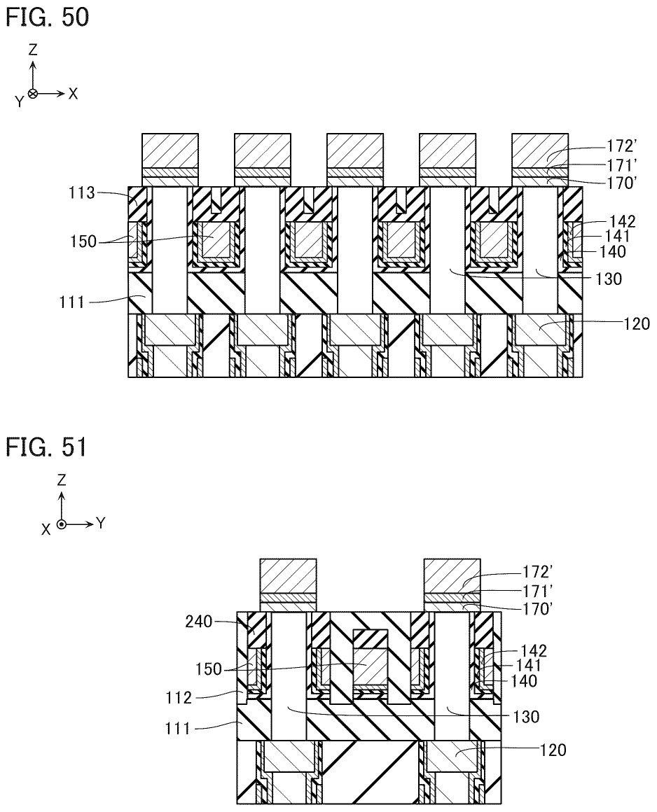

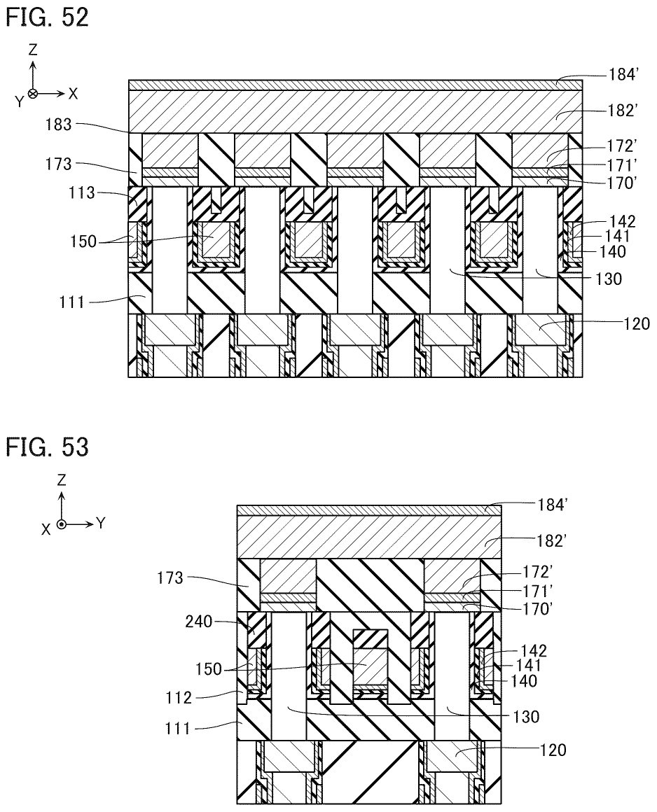

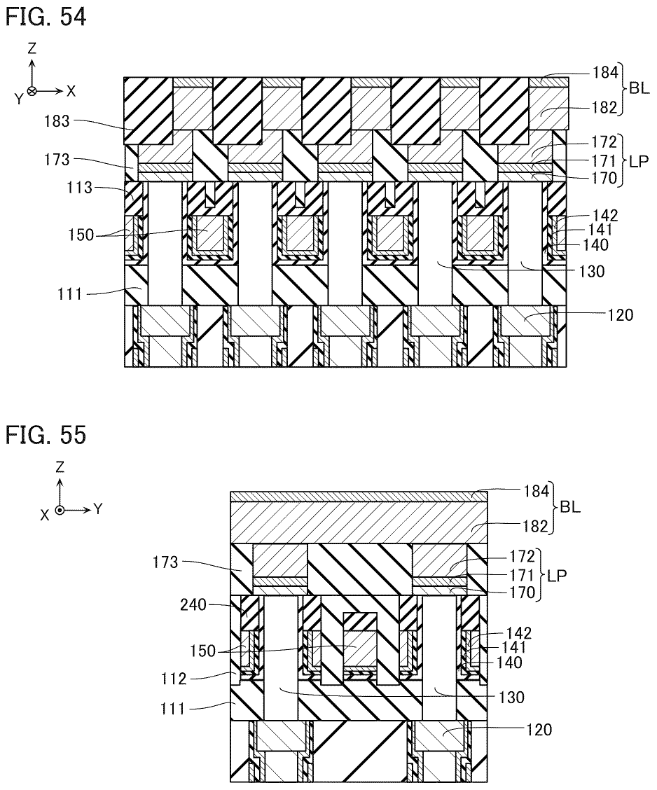

FIG. 10, FIG. 13, FIG. 16, FIG. 19, FIG. 22, FIG. 25, FIG. 28, FIG. 31, FIG. 34, FIG. 36, FIG. 38, FIG. 41, FIG. 44, FIG. 47, FIG. 50, FIG. 52, and FIG. 54 are schematic cross-sectional views of the part corresponding to FIG. 3. FIG. 11, FIG. 14, FIG. 17, FIG. 20, FIG. 23, FIG. 26, FIG. 29, FIG. 32, FIG. 35, FIG. 37, FIG. 39, FIG. 42, FIG. 45, FIG. 48, FIG. 51, FIG. 53, and FIG. 55 are schematic cross-sectional views of the part corresponding to FIG. 8. FIG. 12, FIG. 15, FIG. 18, FIG. 21, FIG. 24, FIG. 27, FIG. 30, FIG. 33, FIG. 40, FIG. 43, FIG. 46, and FIG. 49 are schematic plan views of the part corresponding to FIG. 4. Hereinafter, the drawings according to the manufacturing method are schematically illustrated, and for convenience of description, a part of a configuration and the like is omitted in some cases.

In the manufacturing method, the peripheral circuit layer L_{PC} (FIG. 2), the plate line layer L_{PT} (FIG. 2), and the capacitor layer L_{CP} (FIG. 2) including the through electrodes CC are formed above the substrate Sub (FIG. 1). For example, as illustrated in FIG. 10 to FIG. 13, the insulating layer 111 and a sacrifice layer SC_230 of carbon (C), silicon nitride (SiN), and the like are formed on the upper surface of the capacitor layer L_{CP}. This process is performed by, for example, Chemical Vapor Deposition (CVD).

Next, for example, as illustrated in FIG. 13 to FIG. 15, openings TH_130 are formed. The opening TH_130 extends in the Z-direction, and penetrates the sacrifice layer SC_230 and the insulating layer 111 to expose the conductive layer 120. This process is performed by, for example, Reactive Ion Etching (RIE).

Next, for example, as illustrated in FIG. 16 to FIG. 18, sacrifice layers SC_130 of amorphous silicon (αSi) or the like are formed inside the openings TH_130. This process is performed by, for example, CVD and Chemical Mechanical Planarization (CMP).

Next, for example, as illustrated in FIG. 19 to FIG. 21, the sacrifice layer SC_230 is removed to expose an upper surface of the insulating layer 111, and an upper surface and a part of an outer peripheral surface of the sacrifice layer SC_130. This process is performed by, for example, wet etching.

Next, for example, as illustrated in FIG. 22 to FIG. 24, an insulating layer 140B containing a material similar to that of the insulating layer 140 is formed on the upper surface and a part of the outer peripheral surface of the sacrifice layer SC_130 and the upper surface of the insulating layer 111. This process is performed by, for example, CVD and Atomic Layer Deposition (ALD).

Next, for example, as illustrated in FIG. 25 to FIG. 27, an insulating layer 141B containing a material similar to that of the insulating layer 141 and a conductive layer 142B containing a material similar to that of the barrier conductive layer 142 are formed on the insulating layer 140B in the order. This process is performed by, for example, CVD and ALD. This process is described later in detail.

Next, for example, as illustrated in FIG. 28 to FIG. 30, a conductive layer 150B containing a material similar to that of the conductive layer 150 is formed on the conductive layer 142B. This process is performed by, for example, CVD, ALD.

Next, for example, as illustrated in FIG. 31 to FIG. 33, etchback is performed on the conductive layer 150B, the conductive layer 142B, and the insulating layer 141B to form a conductive layer 150C containing a material similar to that of the conductive layer 150, the barrier conductive layer 142, and the insulating layer 141. This process is performed by, for example, RIE.

Next, for example, as illustrated in FIG. 34 and FIG. 35, on an upper surface of the structure illustrated in FIG. 31 and FIG. 32, an insulating layer 240B of silicon oxide (SiO₂) or the like is formed by CVD and the like, and a mask material MS_PL of silicon nitride (SiN) or the like is formed by photolithography and the like. The mask material MS_PL extends in the X-direction, and a plurality of the mask materials MS_PL are arranged in the Y-direction corresponding to the positions at which the conductive layers 150 are to be formed.

Next, for example, as illustrated in FIG. 36 and FIG. 37, a part of the insulating layer 240B not covered with the mask material MS_PL is removed to form an insulating layer 240 (FIG. 37) separated in the Y-direction. Through this process, a part of an upper surface of the conductive layer 150C is exposed. This process is performed by, for example, RIE.

Next, for example, as illustrated in FIG. 38 to FIG. 40, a part of the conductive layer 150C not covered with the mask material MS_PL and the insulating layer 240 and parts of the insulating layer 141B and the conductive layer 142B in the lower portion thereof are removed to form the conductive layer 150, the insulating layer 141, and the barrier conductive layer 142. Through this process, the conductive layer 150 (FIG. 39, FIG. 40) separated in the Y-direction is formed. This process is performed by, for example, RIE.

Next, for example, as illustrated in FIG. 41 to FIG. 43, an insulating layer containing a material similar to that of the insulating layer 112 is formed on an upper surface of the structure illustrated in FIG. 38 and FIG. 39, and the upper surface of the structure is removed until the sacrifice layer SC_130 is exposed. Through this process, an insulating layer MS_PL′ is formed. This process is performed by, for example, CVD and CMP. After this process, the insulating layer 240 and the insulating layer MS_PL′ disposed above the conductive layer 150 are referred to as the insulating layer 113 in some cases.

Next, for example, as illustrated in FIG. 44 to FIG. 46, the sacrifice layers SC_130 are removed to form openings TH_130b. This process is performed by, for example, wet etching.

Next, for example, as illustrated in FIG. 47 to FIG. 49, the semiconductor layers 130 are formed inside the openings TH_130b. This process is performed by, for example, CVD and CMP.

Next, for example, as illustrated in FIG. 50 and FIG. 51, respective conductive layers containing a material similar to that of the conductive layer 170, the conductive layer 171, and the conductive layer 172 are formed on an upper surface of the structure illustrated in FIG. 47 and FIG. 48. Then, a mask material is formed at positions corresponding to the conductive layer 170, the conductive layer 171, and the conductive layer 172 by photolithography and the like, and a part not covered with the mask material is removed to form a conductive layer 170′, a conductive layer 171′, and a conductive layer 172′. This process is performed by, for example, CVD and RIE.

Next, for example, as illustrated in FIG. 52 and FIG. 53, the insulating layer 173 of silicon oxide (SiO₂) or the like is formed on an upper surface of the structure illustrated in FIG. 50 and FIG. 51, and then, a conductive layer 182′ and a conductive layer 184′ containing a material similar to that of the conductive layer 182 and the conductive layer 184 are formed on an upper surface of the insulating layer 173 and the conductive layer 172′. This process is performed by, for example, CVD and CMP.

Next, for example, as illustrated in FIG. 54 and FIG. 55, the conductive layer 182 and the conductive layer 184 are formed. In this process, for example, a mask material is formed at positions corresponding to the conductive layer 182 and the conductive layer 184 by photolithography and the like, and parts of the conductive layer 182′ and the conductive layer 184′ not covered with the mask material are removed. Through this process, parts of the conductive layer 170′, the conductive layer 171′, and the conductive layer 172′ are simultaneously removed, thereby forming the conductive layer 170, the conductive layer 171, and the conductive layer 172. The insulating layers 183 are formed between stacks of the conductive layers 182 and 184. This process is performed by, for example, RIE, CVD, and CMP.

Next, the wiring layer L_{UL} (FIG. 2) and the like are formed on an upper surface of the structure illustrated in FIG. 54 and FIG. 55, thus the semiconductor device according to the first embodiment is manufactured.

### Process of Forming Insulating Layers 140, 141 and Barrier Conductive Layer 142

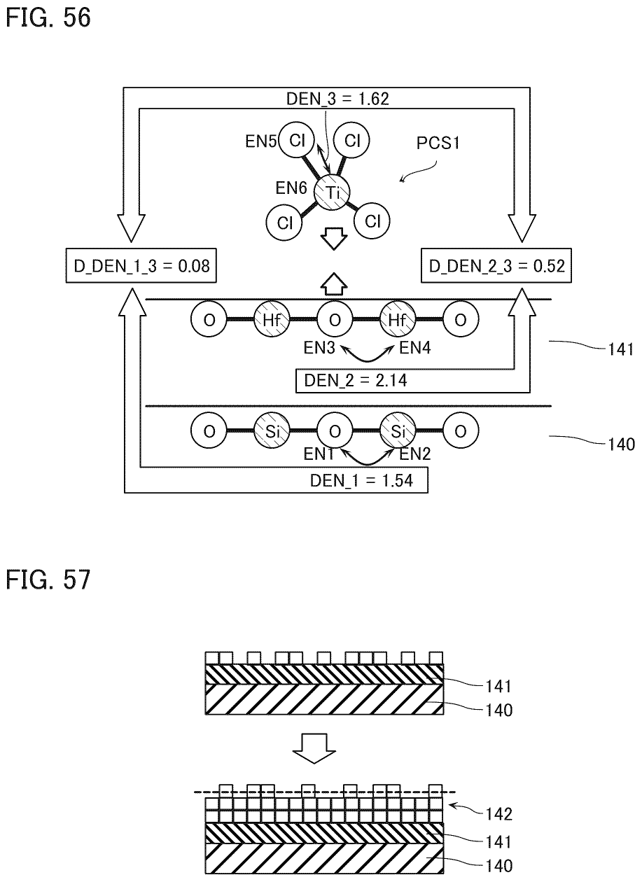

Next, the process of forming the insulating layers 140, 141 and the barrier conductive layer 142 is further described with reference to FIG. 56 to FIG. 58. FIG. 56 to FIG. 58 are schematic views for describing a part of the process of the manufacturing method of the first embodiment.

The barrier conductive layer 142 generally contains a material having the resistivity higher than that of the conductive layer 150. Accordingly, by forming the barrier conductive layer 142 to be thin, the ratio of the conductive layer 150 in the word line WL can be increased to achieve the lowered resistivity of the word line WL.

A method for forming the barrier conductive layer 142 to be thinner is described below.

For example, an electronegativity of one element having the higher atomic concentration of oxygen (O) and nitrogen (N) contained in the insulating layer 140 is defined as an electronegativity EN1. An electronegativity of an element having the highest atomic concentration among the elements contained in the insulating layer 140 other than oxygen (O) and nitrogen (N) is defined as an electronegativity EN2. An absolute value of a difference between the electronegativity EN1 and the electronegativity EN2 is defined as a value DEN_1. An electronegativity of an element having the highest atomic concentration among oxygen (O), chlorine (Cl), and fluorine (F) contained in the insulating layer 141 is defined as an electronegativity EN3. An electronegativity of an element having the highest atomic concentration among the elements contained in the insulating layer 141 other than oxygen (O), chlorine (Cl), and fluorine (F) is defined as an electronegativity EN4. An absolute value of a difference between the electronegativity EN3 and the electronegativity EN4 is defined as a value DEN_2. An electronegativity of an element with the most atoms among chlorine (Cl), nitrogen (N), carbon (C), hydrogen (H), oxygen (O), and fluorine (F) contained in a precursor PCS1 used for forming the barrier conductive layer 142 is defined as an electronegativity EN5. An electronegativity of a metal element contained in the precursor PCS1 is defined as an electronegativity EN6. An absolute value of a difference between the electronegativity EN5 and the electronegativity EN6 is defined as a value DEN_3. The precursor PCS1 is a kind of film formation materials used for forming a film by CVD, ALD, and the like.

For example, FIG. 56 illustrates an example in which the insulating layer 140 is silicon oxide (SiO₂), the insulating layer 141 is hafnium oxide (HfO), and the barrier conductive layer 142 is titanium nitride (TiN). In the example of FIG. 56, titanium chloride (TiCl₄) is used as the precursor PCS1 forming the barrier conductive layer 142.

For example, the electronegativity EN1 of oxygen (O) contained in the insulating layer 140 (silicon oxide (SiO₂)) is 3.44. The electronegativity EN2 of silicon (Si), which is the element having the highest atomic concentration among the elements contained in the insulating layer 140 (silicon oxide (SiO₂)) other than oxygen (O), is 1.90. Therefore, the value DEN_1, which is the absolute value of the difference between the electronegativity EN1 and the electronegativity EN2, is 1.54. Meanwhile, the electronegativity EN3 of oxygen (O) contained in the insulating layer 141 (hafnium oxide (HfO)) is 3.44. The electronegativity EN4 of hafnium (Hf), which is the element having the highest atomic concentration among the elements contained in the insulating layer 141 (hafnium oxide (HfO)) other than oxygen (O), is 1.30. Therefore, the value DEN_2, which is the absolute value of the difference between the electronegativity EN3 and the electronegativity EN4, is 2.14. Meanwhile, the electronegativity EN5 of chlorine (Cl) contained in the precursor PCS1 (titanium chloride (TiCl₄)) is 3.16. The electronegativity EN6 of titanium (Ti) as a metal element contained in the precursor PCS1 (titanium chloride (TiCl₄)) is 1.54. Therefore, the value DEN_3, which is the absolute value of the difference between the electronegativity EN5 and the electronegativity EN6, is 1.62.

Here, the inventor has found that for forming the barrier conductive layer 142 to be thin, an electrostatic force between the precursor PCS1 and a film-formed portion is preferred to be strong.

Therefore, a case where the barrier conductive layer 142 is directly formed on the insulating layer 140 (a case where the insulating layer 141 is not disposed) is compared with a case where the barrier conductive layer 142 is formed on the insulating layer 141, using the precursor PCS1.

For example, the strength of the electrostatic force between the insulating layer 141 and the precursor PCS1 is represented by a value D_DEN_2_3 that is an absolute value of a difference between the value DEN_3 and the value DEN_2. In the example of the materials illustrated in FIG. 56, the value D_DEN_2_3 is a difference between the value DEN_3 (1.62) and the value DEN_2 (2.14), and is 0.52.

For example, the strength of the electrostatic force between the insulating layer 140 and the precursor PCS1 is represented by a value D_DEN_1_3 that is an absolute value of a difference between the value DEN_3 and the value DEN_1. In the example of the materials illustrated in FIG. 56, the value D_DEN_1_3 is a difference between the value DEN_3 (1.62) and the value DEN_1 (1.54), and is 0.08.

In this case, the value D_DEN_2_3 is larger than the value D_DEN_1_3. Therefore, the insulating layer 141 and the precursor PCS1 is a combination that generates a strong electrostatic force compared with a combination of the insulating layer 140 and the precursor PCS1. Accordingly, in the example of the materials illustrated in FIG. 56, forming the insulating layer 141 before forming the barrier conductive layer 142 allows forming the barrier conductive layer 142 to be thinner.

### Relation between Electrostatic Force and Film Formation

A relation between the electrostatic force and a film thickness of the barrier conductive layer 142 is described with reference to FIG. 57. FIG. 57 is a schematic diagram of film formation when a relatively strong electrostatic force is generated between the precursor PCS1 and the insulating layer 141 as a film-formed portion.

The upper part of FIG. 57 is a drawing immediately after starting the film formation of the barrier conductive layer 142. Since the electrostatic force between the insulating layer 141 and the precursor PCS1 is relatively strong, an initial adsorption amount of a film formation material on an upper surface of the insulating layer 141 is relatively large.

The lower part of FIG. 57 is a drawing at completion of the film formation of the barrier conductive layer 142. Since the initial adsorption amount on the insulating layer 141 is large, the film formation material is less likely to be aggregated on the upper surface of the insulating layer 141, and thus, the thin and uniform barrier conductive layer 142 can be formed.

### Precursor Type

While titanium chloride (TiCl₄) is used as the precursor PCS1 in the example illustrated in FIG. 56, the type of the precursor PCS1 can be adjusted depending on the material contained in the barrier conductive layer 142 and the like as appropriate.

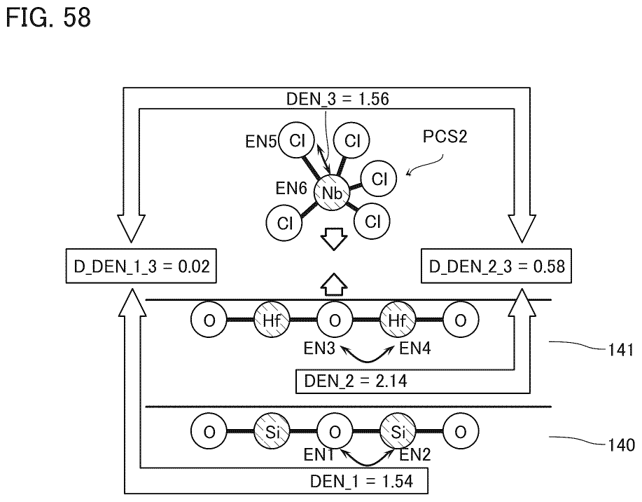

With reference to FIG. 58, an example in which the insulating layer 140 is silicon oxide (SiO₂), the insulating layer 141 is hafnium oxide (HfO), and the barrier conductive layer 142 is niobium nitride (NbN) is described below. In the example below, niobium chloride (NbCl₅) is used as a precursor PCS2 that forms the barrier conductive layer 142 containing niobium nitride (NbN).

For example, the electronegativity EN1 of oxygen (O) contained in the insulating layer 140 (silicon oxide (SiO₂)) is 3.44. The electronegativity EN2 of silicon (Si), which is the element having the highest atomic concentration among the elements contained in the insulating layer 140 (silicon oxide (SiO₂)) other than oxygen (O), is 1.90. Therefore, the value DEN_1, which is the absolute value of the difference between the electronegativity EN1 and the electronegativity EN2, is 1.54. Meanwhile, the electronegativity EN3 of oxygen (O) contained in the insulating layer 141 (hafnium oxide (HfO)) is 3.44. The electronegativity EN4 of hafnium (Hf), which is the element having the highest atomic concentration among the elements contained in the insulating layer 141 (hafnium oxide (HfO)) other than oxygen (O), is 1.30. Therefore, the value DEN_2, which is the absolute value of the difference between the electronegativity EN3 and the electronegativity EN4, is 2.14. Meanwhile, the electronegativity EN5 of chlorine (Cl) contained in the precursor PCS2 (niobium chloride (NbCl₅)) is 3.16. The electronegativity EN6 of niobium (Nb) as a metal element contained in the precursor PCS2 (niobium chloride (NbCl₅)) is 1.60. Therefore, the value DEN_3, which is the absolute value of the difference between the electronegativity EN5 and the electronegativity EN6, is 1.56.

In the above-described example, the value D_DEN_2_3 is a difference between the value DEN_3 (1.56) and the value DEN_2 (2.14), and is 0.58.

The value D_DEN_1_3 is a difference between the value DEN_3 (1.56) and the value DEN_1 (1.54), and is 0.02.

Also in the above-described example, the value D_DEN_2_3 is larger than the value D_DEN_1_3. Therefore, the insulating layer 141 and the precursor PCS2 is a combination that generates a strong electrostatic force compared with a combination of the insulating layer 140 and the precursor PCS2. Accordingly, also in the example of the materials illustrated in FIG. 58, forming the insulating layer 141 before forming the barrier conductive layer 142 allows forming the barrier conductive layer 142 to be thinner.

In the examples of other film formation materials, for the precursor for forming the barrier conductive layer 142 containing tungsten (W), molybdenum (Mo), and the like, for example, the value DEN_3 of tungsten fluoride (WF₆) is 1.62, the value DEN_3 of tungsten chloride (WCl₅) is 0.80, and the value DEN_3 of molybdenum chloride (MoCl₅) is 1.00.

As illustrated in the above-described examples, the value DEN_3 of the film formation material is relatively small. The value DEN_1 of the insulating layer 140 is also relatively small, and the value DEN_1 is often a value close to the value DEN_3. Therefore, with the insulating layer 141 having the value DEN_2 larger than at least the value DEN_1 as a base layer, the difference between the value DEN_3 and the value DEN_2 can be increased. Accordingly, the thin and uniform barrier conductive layer 142 can be formed.

### Atomic Concentration

The atomic concentration can be measured by, for example, Energy Dispersive Spectrometry (EDS), such as Energy-dispersive X-ray spectroscopy. The atomic concentration corresponds to a value obtained by dividing the number of atoms of the element as a measurement target contained in a unit volume by the total number of atoms of all the elements contained in the unit volume, and is expressed with a unit of percent (%).

### Effects

In the semiconductor device according to the embodiment, the thin and uniform barrier conductive layer 142 can be formed. By forming the barrier conductive layer 142 to be thin and uniform, the low resistive conductive layer 150 can be formed with a satisfactory step coverage and a high uniformity. Accordingly, a finer word line WL can be manufactured, and a semiconductor device with a high degree of integration and an excellent characteristic can be manufactured.

By disposing the insulating layer 141 (FIG. 3) having the relatively high dielectric constant between the conductive layer 150 and the insulating layer 140, even when the insulating layers 140, 141 are thinned, the ON current of the select transistor ST can be maintained high.

Since the insulating layer 141 includes the part PT_141b (FIG. 7) provided on one side (lower side) in the Z-direction of the conductive layer 150, when the select transistor ST is turned on, the electrical field intensity of the semiconductor layer 130 at the lower portion with respect to the conductive layer 150 increases, and the ON current of the select transistor ST can be increased.

### Second Embodiment

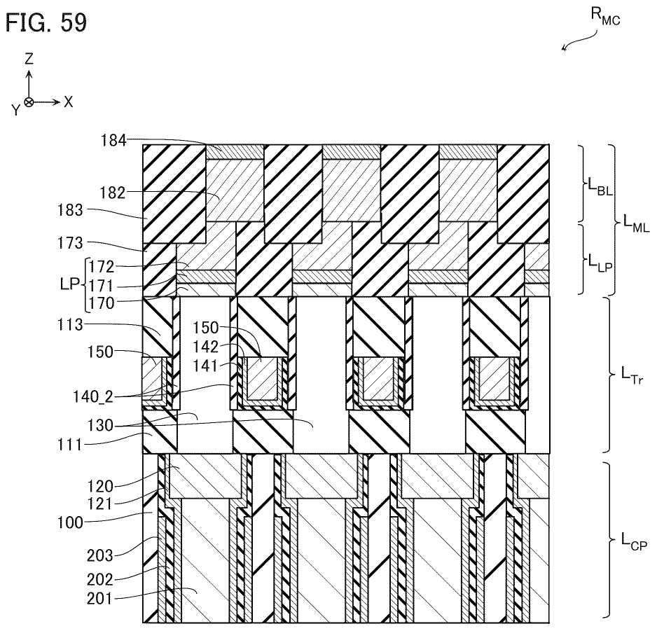

Next, with reference to FIG. 59, a semiconductor device according to the second embodiment is described. FIG. 59 is a schematic cross-sectional view illustrating a configuration of a part of the semiconductor device according to the second embodiment. FIG. 59 illustrates a part corresponding to FIG. 3.

The semiconductor device according to the embodiment is basically configured similarly to the semiconductor device (FIG. 3) according to the first embodiment. However, the semiconductor device (FIG. 59) according to the embodiment includes an insulating layer 140_2 (FIG. 59) instead of the insulating layer 140 (FIG. 3).

The insulating layer 140_2 (FIG. 59) is basically provided similarly to the insulating layer 140 (FIG. 3). However, the insulating layer 140_2 is, different from the insulating layer 140, not disposed between the insulating layer 111 and the conductive layer 150. The insulating layer 140_2 is not provided with a part corresponding to the part PT_140b (FIG. 7, FIG. 8). As described in a manufacturing method (FIG. 60 to FIG. 62) later, the insulating layer 140_2 is formed by plasma oxidation or the like on an exposed surface of the sacrifice layer SC_130 of amorphous silicon (αSi) or the like. Therefore, an interface between the insulating layer 140_2 and the semiconductor layer 130 is provided at the inside (central axis side of the semiconductor layer 130), for example, by about a few nm with respect to an interface between the insulating layer 111 and the semiconductor layer 130.

### Manufacturing Method of Second Embodiment

Next, with reference to FIG. 60 to FIG. 62, a manufacturing method of the semiconductor device according to the embodiment is described. FIG. 60 to FIG. 62 are schematic cross-sectional views and plan views for describing the manufacturing method of the semiconductor device according to the second embodiment.

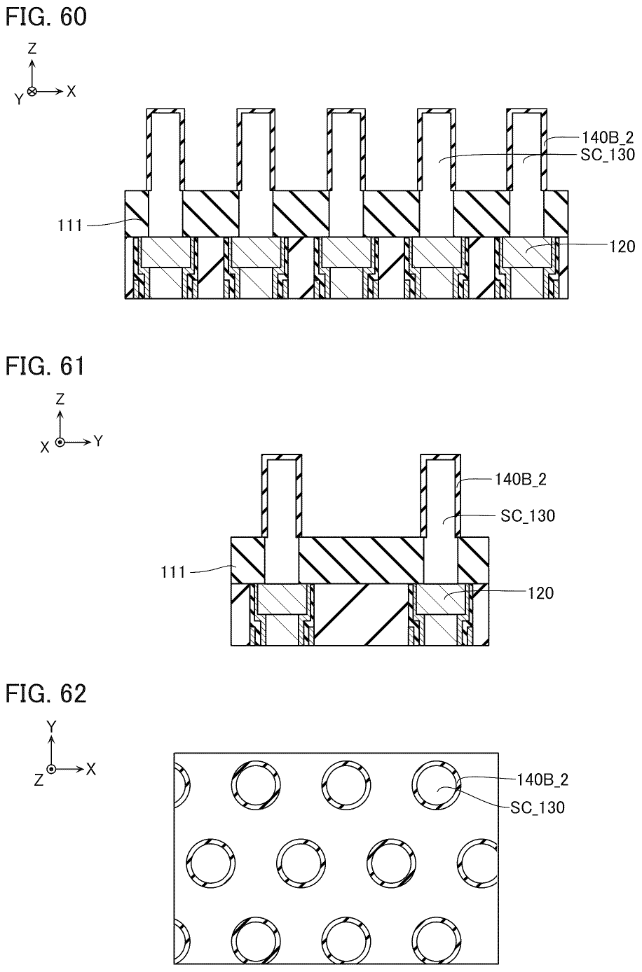

FIG. 60 is a schematic cross-sectional view of a part corresponding to FIG. 59. FIG. 61 is a schematic cross-sectional view corresponding to a part of the configuration illustrated in FIG. 4 taken along a line E-E′ viewed in an arrow direction. FIG. 62 is a plan view illustrating the part similar to FIG. 4. Hereinafter, the drawings according to the manufacturing method are schematically illustrated, and for convenience of description, a part of a configuration and the like is omitted in some cases.

In the manufacturing method, basically, the process similar to that of the manufacturing method (FIG. 10 to FIG. 55) of the first embodiment is performed. However, in the manufacturing method of the second embodiment, a process illustrated in FIG. 60 to FIG. 62 is performed instead of the process described with reference to FIG. 22 to FIG. 24.

In the process illustrated in FIG. 60 to FIG. 62, an insulating layer 140B_2 containing a material similar to that of the insulating layer 140 is formed on the upper surface and a part of the outer peripheral surface of the sacrifice layer SC_130. This process is performed by, for example, plasma oxidation on the exposed surface of the sacrifice layer SC_130 of amorphous silicon (αSi) or the like.

### Other Embodiments

The semiconductor devices according to the first embodiment and the second embodiment have been described above. However, the semiconductor devices according to these embodiments are only examples, and a specific configuration, operations, and the like are adjustable as appropriate.

For example, in the above description, the example in which the capacitor Cap (FIG. 1) is connected to the select transistor ST (FIG. 1) is described. In this example, the shape, structure, and the like of the capacitor Cap are adjustable as appropriate.

Additionally, in the above description, the example in which the capacitor Cap (FIG. 1) is employed as the memory portion connected to the select transistor ST (FIG. 1) is described. However, the memory portion need not be the capacitor Cap. For example, the memory portion may contain a ferroelectric material, a ferromagnet material, a chalcogen material such as GeSbTe, or another material, and may store data using the characteristics of these materials. For example, in any of the structures described above, any of these materials may be included in the insulating layer between the electrodes forming the capacitor Cap.

The above description shows an example in which the semiconductor layer 130 that functions as the channel region of the select transistor ST (FIG. 1) extends in, for example, the Z-direction and has an approximately columnar shape. However, the semiconductor layer 130 may have an approximately cylindrical shape extending in the Z-direction. Further, an insulating layer that has an approximately columnar shape extending in the Z-direction and contains silicon oxide (SiO₂) and the like may be disposed inside the semiconductor layer 130.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a substrate;
an oxide semiconductor layer that extends in a first direction intersecting with a surface of the substrate and contains a first element and oxygen (O);
a first wiring faced to at least a part of the oxide semiconductor layer;
a gate insulating layer that is disposed between the first wiring and the oxide semiconductor layer and at least contains one element of oxygen (O) or nitrogen (N);
an insulating layer that includes a first part provided between the first wiring and the gate insulating layer and contains at least one element among oxygen (O), chlorine (Cl), and fluorine (F); and
a barrier conductive layer that includes a second part provided between the first wiring and the insulating layer, wherein
in a case where:
when an electronegativity of one element having a higher atomic concentration of oxygen (O) and nitrogen (N) contained in the gate insulating layer is a first electronegativity, and
when an electronegativity of a second element having a highest atomic concentration among elements contained in the gate insulating layer other than oxygen (O) and nitrogen (N) is a second electronegativity,
an absolute value of a difference between the first electronegativity and the second electronegativity is a first value; and
when an electronegativity of an element having a highest atomic concentration among oxygen (O), chlorine (Cl), and fluorine (F) contained in the insulating layer is a third electronegativity, and
when an electronegativity of a third element having a highest atomic concentration among elements contained in the insulating layer other than oxygen (O), chlorine (Cl), and fluorine (F) is a fourth electronegativity,
an absolute value of a difference between the third electronegativity and the fourth electronegativity is a second value,
the second value is larger than the first value.

2. The semiconductor device according to claim 1, wherein
the insulating layer further includes a third part provided on one side in the first direction of the first wiring, and
the barrier conductive layer further includes a fourth part provided between the first wiring and the third part.

3. The semiconductor device according to claim 1, wherein
a dielectric constant of the insulating layer is higher than a dielectric constant of the gate insulating layer.

4. The semiconductor device according to claim 1, wherein
a width in a second direction intersecting with the first direction of the insulating layer is 1nm or less.

5. The semiconductor device according to claim 1, wherein
a width in a second direction intersecting with the first direction of the barrier conductive layer is 3 nm or less.

6. The semiconductor device according to claim 1, wherein
the first element is one element selected from a group consisting of indium (In), gallium (Ga), zinc (Zn), magnesium (Mg), aluminum (Al), manganese (Mn), tin (Sn), titanium (Ti), calcium (Ca), and cadmium (Cd).

7. The semiconductor device according to claim 1, wherein
the second element is silicon (Si).

8. The semiconductor device according to claim 1, wherein
the third element is one element selected from a group consisting of aluminum (Al), titanium (Ti), zinc (Zn), hafnium (Hf), yttrium (Y), scandium (Sc), tantalum (Ta), lanthanum (La), and vanadium (V).

9. The semiconductor device according to claim 1, wherein
the barrier conductive layer contains a first metal element and nitrogen (N), and
the first metal element is one element selected from a group consisting of titanium (Ti), niobium (Nb), tungsten (W), and molybdenum (Mo).

10. The semiconductor device according to claim 1, further comprising
a capacitor layer disposed on one side in the first direction of the oxide semiconductor layer, wherein
the capacitor layer includes a capacitor structure electrically connected to the oxide semiconductor layer.

11. A semiconductor device comprising:
a substrate;
an oxide semiconductor layer that extends in a first direction intersecting with a surface of the substrate and contains a first element and oxygen (O);
a first wiring faced to at least a part of the oxide semiconductor layer;
a gate insulating layer that is disposed between the first wiring and the oxide semiconductor layer and at least contains one element of oxygen (O) or nitrogen (N);
an insulating layer that includes a first part provided between the first wiring and the gate insulating layer and contains at least one element among oxygen (O), chlorine (Cl), and fluorine (F); and
a barrier conductive layer that is disposed between the first wiring and the insulating layer and includes a second part, wherein
a second element having a highest atomic concentration among elements contained in the gate insulating layer other than oxygen (O) and nitrogen (N) is silicon (Si), and
a third element having a highest atomic concentration among elements contained in the insulating layer other than oxygen (O), chlorine (Cl), and fluorine (F) is one element selected from a group consisting of aluminum (Al), titanium (Ti), zinc (Zn), hafnium (Hf), yttrium (Y), scandium (Sc), tantalum (Ta), lanthanum (La), and vanadium (V).

12. The semiconductor device according to claim 11, wherein
the insulating layer further includes a third part provided on one side in the first direction of the first wiring, and
the barrier conductive layer further includes a fourth part provided between the first wiring and the third part.

13. The semiconductor device according to claim 11, wherein
a dielectric constant of the insulating layer is higher than a dielectric constant of the gate insulating layer.

14. The semiconductor device according to claim 11, wherein
a width in a second direction intersecting with the first direction of the insulating layer is 1 nm or less.

15. The semiconductor device according to claim 11, wherein
a width in a second direction intersecting with the first direction of the barrier conductive layer is 3 nm or less.

16. The semiconductor device according to claim 11, wherein
the first element is one element selected from a group consisting of indium (In), gallium (Ga), zinc (Zn), magnesium (Mg), aluminum (Al), manganese (Mn), tin (Sn), titanium (Ti), calcium (Ca), and cadmium (Cd).

17. The semiconductor device according to claim 1, wherein
the barrier conductive layer contains a first metal element and nitrogen (N), and
the first metal element is one element selected from a group consisting of titanium (Ti), niobium (Nb), tungsten (W), and molybdenum (Mo).

18. The semiconductor device according to claim 1, further comprising
a capacitor layer between the substrate and the oxide semiconductor layer, wherein
the capacitor layer includes a capacitor structure electrically connected to the oxide semiconductor layer.

19. A manufacturing method of a semiconductor device, wherein
the semiconductor device includes:
a substrate;
an oxide semiconductor layer that extends in a first direction intersecting with a surface of the substrate and contains a first element and oxygen (O);
a first wiring faced to at least a part of the oxide semiconductor layer;
a gate insulating layer that is disposed between the first wiring and the oxide semiconductor layer and at least contains one element of oxygen (O) or nitrogen (N);
an insulating layer that includes a first part provided between the first wiring and the gate insulating layer and contains at least one element among oxygen (O), chlorine (Cl), and fluorine (F); and
a barrier conductive layer that includes a second part provided between the first wiring and the insulating layer and contains a first metal element,
when an electronegativity of one element having a higher atomic concentration of oxygen (O) and nitrogen (N) contained in the gate insulating layer is a first electronegativity, and
when an electronegativity of a second element having a highest atomic concentration among all elements contained in the gate insulating layer other than oxygen (O) and nitrogen (N) is a second electronegativity,
an absolute value of a difference between the first electronegativity and the second electronegativity is a first value,
when an electronegativity of an element having a highest atomic concentration among oxygen (O), chlorine (Cl), and fluorine (F) contained in the insulating layer is a third electronegativity, and
when an electronegativity of a third element having a highest atomic concentration among all elements contained in the insulating layer other than oxygen (O), chlorine (Cl), and fluorine (F) is a fourth electronegativity,
an absolute value of a difference between the third electronegativity and the fourth electronegativity is a second value,
the method comprises the steps of:
forming the gate insulating layer;
forming the insulating layer on the gate insulating layer; and
forming the barrier conductive layer on the insulating layer using a precursor containing the first metal element, and
when an electronegativity of an element having a most atoms among chlorine (Cl), nitrogen (N), carbon (C), hydrogen (H), oxygen (O), and fluorine (F) contained in the precursor is a fifth electronegativity, and
when an electronegativity of the first metal element contained in the precursor is a sixth electronegativity,
an absolute value of a difference between the fifth electronegativity and the sixth electronegativity is a third value,
an absolute value of a difference between the third value and the second value is larger than an absolute value of a difference between the third value and the first value.

20. The manufacturing method of the semiconductor device according to claim 19, further comprising
forming the first wiring on the barrier conductive layer by Chemical Vapor Deposition (CVD) or Atomic Layer Deposition (ALD).
